(19) United States
(12) Patent Application Publication
(10) Pub. No.: US 2026/0020476 A1
(43) Pub. Date: Jan. 15, 2026

(54) DISPLAY SUBSTRATE AND PREPARATION METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Saijun SUN, Beijing (CN); Feng BAI, Beijing (CN); Hexiong LI, Beijing (CN); Guowei SU, Beijing (CN); Jiapei REN, Beijing (CN); Shanjie YANG, Beijing (CN); Nan DU, Beijing (CN); Yong ZHOU, Beijing (CN); Yi ZHOU, Beijing (CN); Baojie ZHANG, Beijing (CN); Suoping PENG, Beijing (CN)

(21) Appl. No.: 18/992,197

(22) PCT Filed: Mar. 19, 2024
(86) PCT No.: PCT/CN2024/082377

§ 371 Date: Jan. 8, 2025

(30) Foreign Application Priority Data
Apr. 28, 2023 (CN) 202310486035.X

(51) Int. Cl. H10K 59/80; H10K 59/12; H10K 59/121

(52) U.S. Cl. CPC H10K 59/873; H10K 59/1201; H10K 59/1213

(57) ABSTRACT

A display substrate and a preparation method therefor, and a display device. The display substrate comprises a hole region, a transition region surrounding the hole region, and a display region surrounding the transition region, wherein the transition region is provided with an isolation structure surrounding the hole region, and the isolation structure comprises at least one isolation groove; the display substrate comprises a base, and the isolation groove comprises a groove and a blocking edge arranged on the side of the groove away from the base; and in a direction perpendicular to the base, the transition region comprises a first structure layer and a second structure layer which are sequentially stacked in the direction away from the base, the first structure layer comprises a blocking layer, the groove extends through the second structure layer and exposes at least part of the surface of the blocking layer.

### CROSS-REFERENCE TO RELATED APPLICATION

The present application is a U.S. National Phase Entry of International Application No. PCT/CN2024/082377 having an international filing date of Mar. 19, 2024, which claims priority of Chinese Patent Application No. 202310486035.X, filed to the CNIPA on Apr. 28, 2023 and entitled “Display Substrate and Preparation Method Therefor, and Display Device”. Contents of the above-identified applications are incorporated herein by reference.

### TECHNICAL FIELD

The present disclosure relates to, but is not limited to, the field of display technologies, and in particular to a display substrate and a preparation method therefor, and a display device.

### BACKGROUND

With the rapid development of smartphones towards full screens, screen-to-body ratio requirements are getting higher and higher, market demands for punch-hole screens are increasing, and semiconductor encapsulation technologies to meet these demands are also constantly developing. At present, the thin film encapsulation (TFE) is a common encapsulation technology for organic light-emitting diode (OLED) displays. Due to the encapsulation reliability requirements of the TFE, an evaporated light-emitting functional film layer is not allowed to be present below an edge of a TFE layer. Otherwise, after cutting, water vapor, oxygen and the like will penetrate into the interior of the OLED display through the organic evaporated film layer of the cut section, affecting the reliability of the OLED display encapsulation. Therefore, how to improve the encapsulation reliability of the thin film encapsulation at an opening position within the OLED display has become an urgent problem to be solved.

### SUMMARY

The following is a summary of subject matters described herein in detail. This summary is not intended to limit the protection scope of claims.

An embodiment of the present disclosure provides a display substrate including a hole region, a transition region surrounding the hole region, and a display region surrounding the transition region. The transition region is provided with an isolation structure surrounding the hole region, and the isolation structure includes at least one isolation undercut.

The display substrate includes a base, and the isolation undercut includes a groove and a blocking edge disposed on a side of the groove away from the base. In a direction perpendicular to the base, the transition region includes a first structure layer and a second structure layer sequentially stacked in a direction away from the base, the first structure layer includes a blocking layer, and the groove penetrates the second structure layer and exposes at least a portion of a surface of the blocking layer. The blocking edge is disposed on a surface of the second structure layer away from the base, and a portion of the blocking edge extends in a direction parallel to the base and protrudes from a side wall of the groove.

An embodiment of the present disclosure further provides a display device including the display substrate described above.

An embodiment of the present disclosure further provides a method for preparing the display substrate, including: sequentially forming a first structure layer and a second structure layer on a base of a transition region, the first structure layer including a blocking layer, the second structure layer being provided with a groove, the groove penetrating the second structure layer and exposing at least a portion of a surface of the blocking layer; forming a filling layer within the groove, the filling layer filling and leveling up the groove; forming a blocking edge on a surface of the second structure layer away from the base, a portion of the blocking edge extending onto a surface of the filling layer away from the base in a direction parallel to the base; and removing the filling layer.

Other aspects of the present disclosure may be comprehended after the drawings and the detailed descriptions are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of components in the drawings do not reflect actual scales, and are only intended to schematically illustrate contents of the present disclosure.

FIG. 1 is a schematic diagram of a planar structure of a display substrate according to some exemplary embodiments;

FIG. 2a is a schematic diagram of a cross-sectional structure taken along A-A of FIG. 1 according to some exemplary embodiments;

FIG. 2b is a schematic diagram of a cross-sectional structure taken along A-A of FIG. 1 according to other exemplary embodiments;

FIG. 2c is a schematic diagram of a cross-sectional structure taken along A-A of FIG. 1 according to some further exemplary embodiments;

FIG. 3 is a schematic diagram of a cross-sectional structure taken along A-A of FIG. 1 according to some further exemplary embodiments;

FIG. 4 is a schematic diagram of a cross-sectional structure taken along A-A of FIG. 1 according to some further exemplary embodiments;

FIG. 5 is a schematic diagram of a cross-sectional structure taken along A-A of FIG. 1 according to some further exemplary embodiments;

FIG. 6 is a schematic diagram of a cross-sectional structure taken along A-A of FIG. 1 according to some further exemplary embodiments;

FIG. 7a is a schematic diagram of a structure of a display substrate after a second interlayer insulation layer is formed according to some exemplary embodiments;

FIG. 7b is a schematic diagram of a structure of a display substrate after a first source-drain metal layer is formed according to some exemplary embodiments;

FIG. 7c is a schematic diagram of a structure of a display substrate after a first planarization layer is formed according to some exemplary embodiments;

FIG. 7d is a schematic diagram of a structure of a display substrate after a second source-drain metal layer is formed according to some exemplary embodiments;

FIG. 7e is a schematic diagram of a structure of a display substrate after a pixel definition layer is formed according to some exemplary embodiments;

FIG. 7f is a schematic diagram of a structure of a display substrate after a filling layer is removed according to some exemplary embodiments;

FIG. 8a is a schematic diagram of a structure of a display substrate after a third gate insulation layer is formed according to some exemplary embodiments;

FIG. 8b is a schematic diagram of a structure of a display substrate after a third gate metal layer is formed according to some exemplary embodiments;

FIG. 8c is a schematic diagram of a structure of a display substrate after a second interlayer insulation layer is formed according to some exemplary embodiments;

FIG. 8d is a schematic diagram of a structure of a display substrate after a first source-drain metal layer is formed according to some exemplary embodiments;

FIG. 8e is a schematic diagram of a structure of a display substrate after a first planarization layer is formed according to some other exemplary embodiments;

FIG. 8f is a schematic diagram of a structure of a display substrate after a second source-drain metal layer is formed according to some exemplary embodiments;

FIG. 8g is a schematic diagram of a structure of a display substrate after a first electrode is formed according to some exemplary embodiments;

FIG. 8h is a schematic diagram of a structure of a display substrate after a pixel definition layer is formed according to some exemplary embodiments;

FIG. 8i is a schematic diagram of a structure of a display substrate after a filling layer is removed according to some exemplary embodiments;

FIG. 9a is a schematic diagram of a structure of a display substrate after a second interlayer insulation layer is formed according to some exemplary embodiments;

FIG. 9b is a schematic diagram of a structure of a display substrate after a first source-drain metal layer is formed according to some exemplary embodiments;

FIG. 9c is a schematic diagram of a structure of a display substrate after a first planarization layer is formed according to some exemplary embodiments;

FIG. 9d is a schematic diagram of a structure of a display substrate after a second source-drain metal layer is formed according to some exemplary embodiments;

FIG. 9e is a schematic diagram of a structure of a display substrate after a first electrode is formed according to some exemplary embodiments;

FIG. 9f is a schematic diagram of a structure of a display substrate after a pixel definition layer is formed according to some exemplary embodiments; and

FIG. 9g is a schematic diagram of a structure of a display substrate after a filling layer is removed according to some exemplary embodiments.

### REFERENCE NUMBERS

10 base, 20 drive structure layer, 21 first buffer layer, 22 first gate insulation layer, 23 second gate insulation layer, 24 first interlayer insulation layer, 25 third gate insulation layer, 26 second interlayer insulation layer, 27 first planarization layer, 28 second planarization layer, 30 light-emitting structure layer, 31 first electrode, 32 pixel definition layer, 33 light-emitting functional layer, 34 second electrode layer, 40 encapsulation structure layer, 41 first encapsulation layer, 42 second encapsulation layer, 43 third encapsulation layer, 50 isolation structure, 51 isolation undercut, 52 isolation column, 60 isolation dam, 71 first isolation layer, 72 blocking wall, 73 second isolation layer, 81 first groove, 82 second groove, 83 third groove, 84 first metal ring, 85 second metal ring, 86 first blocking edge, 87 second blocking edge, 91 first protruding ring, 92 second protruding ring, 100 display region, 200 hole region, 201 first transistor, 202 second transistor, 203 storage capacitor, 204 connection electrode, 261 first sublayer, 262 second sublayer, 271 filling layer, 300 transition region, 511 groove, 512 blocking edge, 513 blocking layer, 514 protruding ring, 521 first isolation portion, 522 second isolation portion, 523 column base, 2011 first active layer, 2012 first gate electrode, 2013 first source electrode, 2014 first drain electrode, 2021 second active layer, 2022 second gate electrode, 2023 second source electrode, 2024 second drain electrode, 2031 first electrode plate, and 2032 second electrode plate.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

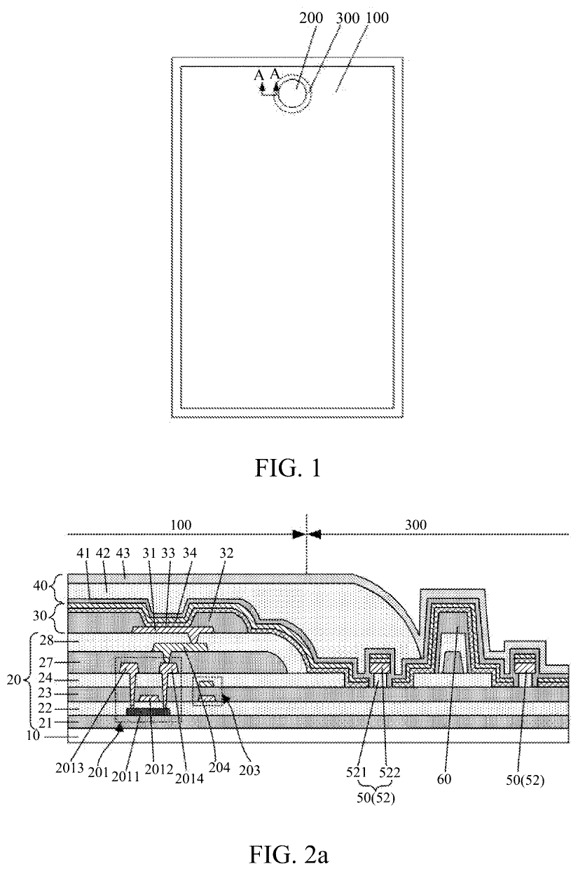

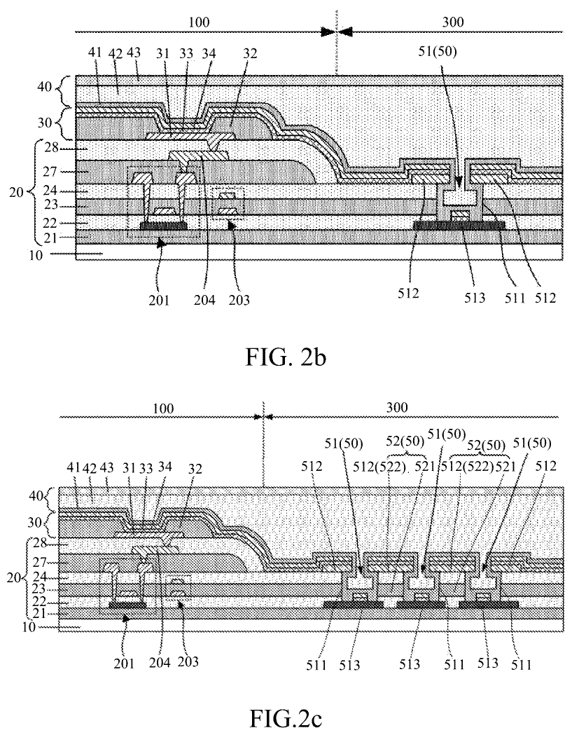

As shown in FIGS. 1, 2a and 2b, FIG. 1 is a schematic diagram of a planar structure of a display substrate according to some exemplary embodiments, FIG. 2a is a schematic diagram of a cross-sectional structure taken along A-A of FIG. 1 according to some exemplary embodiments, and FIG. 2b is a schematic diagram of a cross-sectional structure taken along A-A of FIG. 1 according to other exemplary embodiments. The display substrate includes a hole region 200, a transition region 300 surrounding the hole region 200, and a display region 100 surrounding the transition region 300.

Exemplarily, the display region 100 includes a drive structure layer 20, a light-emitting structure layer 30, and an encapsulation structure layer 40 sequentially stacked on a base 10.

The drive structure layer 20 includes multiple pixel drive circuits, and the pixel drive circuit includes multiple transistors (T) and a storage capacitor 203 (C). FIG. 2a shows one first transistor 201. The pixel drive circuit may adopt a structure such as 3T1C, 4T1C, 5T1C, 5T2C, 6T1C, or 7T1C, and the present disclosure is not limited thereto.

The light-emitting structure layer 30 includes multiple light-emitting elements, and the light-emitting element may be OLED (Organic Light-Emitting Diode) or QLED (Quantum Dot Light-Emitting Diode) devices. The light-emitting element includes a first electrode 31, a light-emitting functional layer 33, and a second electrode layer 34 sequentially stacked in a direction away from the base 10. The light-emitting functional layer 33 includes an organic light-emitting layer, and may further include any one or more film layers of a hole injection layer, a hole transporting layer, and an electron blocking layer located between the first electrode 31 and the organic light-emitting layer, and any one or more film layers of an electron injection layer, an electron transporting layer, and a hole blocking layer located between the second electrode layer 34 and the organic light-emitting layer. The first electrode 31 of the light-emitting element is connected to the pixel drive circuit, and the light-emitting element emits light when driven by the pixel drive circuit. In a direction perpendicular to the base 10, the light-emitting structure layer 30 includes a first electrode layer, a pixel definition layer 32, a light-emitting functional layer 33, and a second electrode layer 34 sequentially disposed. The first electrode layer includes multiple first electrodes 31, and the pixel definition layer 32 is disposed on a side of the multiple first electrodes 31 away from the base 10 and is provided with multiple pixel openings. The pixel openings expose the first electrodes 31, and the light-emitting functional layer 33 and the second electrode layer 34 are sequentially stacked on a side of the first electrode 31 away from the base 10.

The encapsulation structure layer 40 may include a first encapsulation layer 41, a second encapsulation layer 42, and a third encapsulation layer 43 that are sequentially stacked in a direction away from the base 10. Main materials of the first encapsulation layer 41 and the third encapsulation layer 43 (materials with the largest component in the film layers) are inorganic materials which may include at least one of silicon oxide (SiOx), silicon nitride (SiNx), and silicon oxynitride (SiOxNy), and a main material of the second encapsulation layer 42 may be an organic material, such as epoxy resin, so as to facilitate encapsulation and avoid erosion of water vapor. The first encapsulation layer 41 and the third encapsulation layer 43 may be formed using a chemical vapor deposition (CVD) process, and the second encapsulation layer 42 may be formed using an ink jet printing (IJP) process.

Exemplarily, the transition region 300 is provided with an isolation structure 50 surrounding the hole region 200. The isolation structure 50 is configured to isolate the light-emitting functional layer 33 and the second electrode layer 34 of the transition region 300, so as to avoid the erosion of water and oxygen from the hole region 200 to the display region 100 along the light-emitting functional layer 33 and the second electrode layer 34, and to protect the light-emitting functional layer 33 and the second electrode layer 34 of the display region 100 from being eroded by water and oxygen. The isolation structure 50 may include at least one isolation undercut 51 (shown in FIG. 2b) or/and at least one isolation column 52 (shown in FIG. 2a), both of which are disposed around the hole region 200. The number of isolation structures 50 may be one or more, and the embodiments of the present disclosure do not limit the number of isolation structures 50.

The transition region 300 may further be provided with an isolation dam 60 disposed around the hole region 200. In the process of forming the second encapsulation layer 42 of the encapsulation structure layer 40 by the ink jet printing process, the ink jet printing material may overflow, and the isolation dam 60 may function in preventing the ink jet printing material from overflow. A surface of the isolation dam 60 away from the base 10 is higher than a surface of the isolation column 52 away from the base 10. The number of isolation dams 60 may be one or more, and the embodiments of the present disclosure does not limit the number of isolation dams 60. At least one isolation structure 50 may be located on a side of the isolation dam 60 facing the display region 100 or/and on a side of the isolation dam 60 facing the hole region 200.

In some exemplary embodiments, as shown in FIGS. 2a and 2b, in a direction perpendicular to the base 10, the drive structure layer 20 may include a first buffer layer 21, a first semiconductor layer, a first gate insulation layer 22, a first gate metal layer, a second gate insulation layer 23, a second gate metal layer, a first interlayer insulation layer 24, a first source-drain metal layer, a first planarization layer 27, a second source-drain metal layer, and a second planarization layer 28 sequentially disposed in a direction away from the base 10. The first semiconductor layer may include a first active layer 2011 of a first transistor 201. The first gate metal layer may include a first gate electrode 2012 of the first transistor 201 and one electrode plate of the storage capacitor 203. The second gate metal layer may include the other electrode plate of the storage capacitor 203. The first source-drain metal layer includes a first source electrode 2013 and a first drain electrode 2014 of the first transistor 201. The second source-drain metal layer includes a connection electrode 204 connected to the first source electrode 2013 or the first drain electrode 2014 of the first transistor 201, and the connection electrode 204 is further connected to the first electrode 31.

In some examples of the present embodiment, as shown in FIG. 2a, the isolation structure 50 may include at least one isolation column 52 disposed around the hole region. The isolation column 52 may include a first isolation portion 521 and a second isolation portion 522 sequentially disposed in a direction away from the base 10. The second isolation portion 522 is disposed protruding from the first isolation portion 521 on a side of the isolation column 52 facing the display region 100 or/and the hole region 200.

A material of the first isolation portion 521 may be an inorganic insulation material. The first isolation portion 521 may be disposed in the same layer as the first interlayer insulation layer 24, and the first interlayer insulation layer 24 may have a single layer structure or a multiple layer structure. For example, the first interlayer insulation layer 24 may include a silicon oxide film layer and a silicon nitride film layer sequentially stacked in a direction away from the base 10, and the first isolation portion 521 include the silicon oxide film layer and the silicon nitride film layer sequentially stacked in the direction away from the base 10. The silicon nitride film layer may have a thickness of 0.5 μm to 1 μm (micron), for example, it may be 0.8 μm.

A material of the second isolation portion 522 may be a metal material. The second isolation portion 522 may be disposed in the same layer as the first source electrode 2013 and the first drain electrode 2014 of the first transistor 201. Alternatively, the second isolation portion 522 may be disposed in the same layer as the connection electrode 204. Alternatively, the second isolation portion 522 may include a first sub-isolation portion and a second sub-isolation portion sequentially stacked in the direction away from the base 10. The first sub-isolation portion may be disposed in the same layer as the first source electrode 2013 and the first drain electrode 2014 of the first transistor 201, and the second sub-isolation portion may be disposed in the same layer as the connection electrode 204.

In this embodiment, a thickness of the first interlayer insulation layer 24 may be designed to be thicker (for example, the thickness of the silicon nitride film layer in the first interlayer insulation layer 24 may be designed to be thicker in some examples), and correspondingly, a thickness of the first isolation portion 521 is thicker. This is beneficial to improving the isolation effect of the isolation column 52 on the light-emitting functional layer 33 and the second electrode layer 34, and preventing the light-emitting functional layers 33 located on both sides of the isolation column 52 from being connected into a conductive path through the second isolation portion 522 having a conductive function of the isolation column 52 after being isolated by the isolation column 52, thereby avoiding the resulting display failure.

Herein, “A and B are disposed in the same layer” means that the film layers of A and the film layers of B are derived from the same thin film, which may be a single layer structure or a multiple layer composite structure, and the film layers of A and the film layers of B may be the same or different. “A and B are disposed in the same layer” can be understood as meaning that the same thin film is subjected to the same patterning process to form A and B at the same time, or that the same thin film is subjected to the same patterning process to form A′ and B′ at the same time, A′ is subjected to further processing (such as etching, etc.) to obtain A, and B′ is subjected to further processing (such as etching, etc.) to obtain B.

In some examples of the present embodiment, as shown in FIG. 2b, the isolation structure 50 may include at least one isolation undercut 51 disposed around the hole region. The isolation undercut 51 includes a groove 511 and a blocking edge 512 disposed on a side of the groove 511 away from the base 10. In a direction perpendicular to the base 10, the transition region 300 includes a first structure layer and a second structure layer sequentially stacked in a direction away from the base 10. The first structure layer includes a blocking layer 513. The groove 511 penetrates the second structure layer and exposes at least a portion of a surface of the blocking layer 513 (the surface away from the base 10). The blocking edge 512 is disposed on a surface of the second structure layer away from the base 10, and a portion of the blocking edge 512 extends in a direction parallel to the base 10 and protrudes from a side wall of the groove 511.

The blocking layer 513 may be disposed in the same layer as the first active layer 2011 (the first semiconductor layer) of the first transistor 201. The second structure layer may include multiple inorganic insulation layers stacked, for example, may include a first inorganic insulation layer, a second inorganic insulation layer, and a third inorganic insulation layer sequentially stacked in the direction away from the base 10. The first inorganic insulation layer is disposed in the same layer as the first gate insulation layer 22, the second inorganic insulation layer is disposed in the same layer as the second gate insulation layer 23, and the third inorganic insulation layer is disposed in the same layer as the first interlayer insulation layer 24.

The blocking edge 512 may be disposed in the same layer as the connection electrode 204. Alternatively, the blocking edge 512 may be disposed in the same layer as the first source electrode 2013 and the first drain electrode 2014.

An orthographic projection of the blocking edge 512 on the base 10 may include an orthographic projection of an edge of the blocking layer 513 away from the groove 511 on the base 10. Alternatively, the orthographic projection of the blocking edge 512 on the base 10 may fall within the orthographic projection of the blocking layer 513 on the base 10. This embodiment is not limited to this.

In this embodiment, by providing the isolation undercut 51 surrounding the hole region 200 in the transition region 300, the organic light-emitting functional film layer evaporated in the transition region 300 can be isolated, thereby preventing the intrusion of external water vapor and oxygen into the display region 100 from the hole region 200 through the organic light-emitting functional film layer, and ensuring encapsulation reliability. In addition, using the blocking layer 513, it is possible to help control the structural morphology of the formed groove 511 in the process of etching to form the groove 511. For example, a portion of a side wall of the groove 511 close to the blocking layer 513 may be more recessed in a direction away from the center of the groove 511, improving the isolation effect of the isolation undercut 51.

In some exemplary embodiments, as shown in FIG. 2c, which is a schematic diagram of a cross-sectional structure taken along A-A of FIG. 1 according to some further exemplary embodiments, the isolation structure 50 may include multiple isolation undercuts 51 (three isolation undercuts 51 are schematically shown in FIG. 2c). The isolation undercuts 51 are disposed around the hole region. The isolation undercut 51 includes the groove 511 and the blocking edge 512 disposed on a side of the groove 511 away from the base 10. In a direction perpendicular to the base 10, the transition region 300 includes the first structure layer and the second structure layer sequentially stacked in a direction away from the base 10. The first structure layer includes the blocking layer 513. The groove 511 penetrates the second structure layer and exposes at least a portion of a surface of the blocking layer 513 (the surface away from the base 10). The blocking edge 512 is disposed on a surface of the second structure layer away from the base 10, and a portion of the blocking edge 512 extends in a direction parallel to the base 10 and protrudes from a side wall of the groove 511. Each isolation undercut 51 may include two blocking edges 512 in which the two blocking edges 512 each are located on both sides of the groove 511.

The isolation structure 50 may further include at least one isolation column 52. The isolation column 52 includes the first isolation portion 521 and the second isolation portion 522 sequentially disposed in a direction away from the base 10. The second isolation portion 522 is disposed protruding from the first isolation portion 521 on a side of the isolation column 52 facing the display region 100 or/and the hole region 200.

One isolation column 52 may be formed between two adjacent isolation undercuts 51. The blocking edge 512 and the second isolation portion 522 may be disposed in the same layer and made of the same material. The second structure layer between the two adjacent grooves 511 is the first isolation portion 521. The second isolation portion 522 of one isolation column 52 may serve as one of the blocking edges 512 of the two adjacent isolation undercuts 51.

The two adjacent blocking layers 513 may not be connected, and at least a portion of an orthographic projection of the second isolation portion 522 on the base 10 may not overlap with an orthographic projection of the two adjacent blocking layers 513 on the base 10.

In other embodiments, at least two adjacent blocking layers 513 may be integrally connected, and an orthographic projection of the at least two adjacent blocking layers 513 connected integrally on the base 10 may include an orthographic projection of at least one isolation column 52 on the base 10. In the present embodiment, multiple blocking layers 513 in FIG. 2c may be integrally connected.

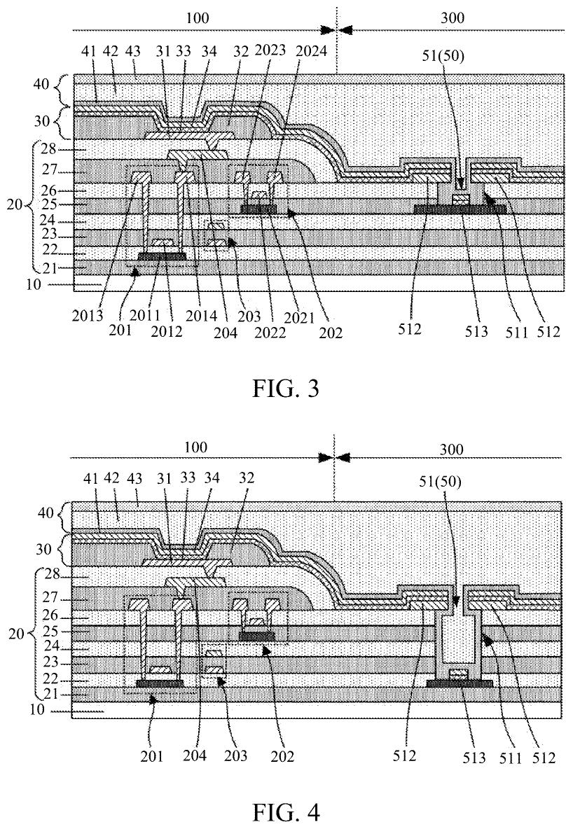

In some exemplary embodiments, as shown in FIGS. 3 and 4, FIG. 3 is a schematic diagram of a cross-sectional structure taken along A-A of FIG. 1 according to some further exemplary embodiments, and FIG. 4 is a schematic diagram of a cross-sectional structure taken along A-A of FIG. 1 according to some further exemplary embodiments. In a direction perpendicular to the base 10, the drive structure layer 20 may include a first buffer layer 21, a first semiconductor layer, a first gate insulation layer 22, a first gate metal layer, a second gate insulation layer 23, a second gate metal layer, a first interlayer insulation layer 24, a second semiconductor layer, a third gate insulation layer 25, a third gate metal layer, a second interlayer insulation layer 26, a first source-drain metal layer, a first planarization layer 27, a second source-drain metal layer, and a second planarization layer 28, which are sequentially disposed in a direction away from the base 10. The first semiconductor layer may include a first active layer 2011 of a first transistor 201. The first gate metal layer may include a first gate electrode 2012 of the first transistor 201 and one electrode plate of a storage capacitor 203. The second gate metal layer may include the other electrode plate of the storage capacitor 203. The second semiconductor layer may include a second active layer 2021 of a second transistor 202. The third gate metal layer may include a second gate electrode 2022 of the second transistor 202. The first source-drain metal layer includes a first source electrode 2013 and a first drain electrode 2014 of the first transistor 201, and a second source electrode 2023 and a second drain electrode 2024 of the second transistor 202. The second source-drain metal layer includes a connection electrode 204 connected to the first source electrode 2013 or the first drain electrode 2014 of the first transistor 201, and the connection electrode 204 is also connected to a first electrode 31.

In some examples of the present embodiment, the display substrate may be a low-temperature polycrystalline oxide (LTPO) display substrate. The multiple transistors of the pixel drive circuit may include a low-temperature polysilicon (LTPS) thin film transistor and an oxide thin film transistor. The oxide thin film transistor may be an indium gallium zinc oxide (IGZO) thin film transistor. The first transistor 201 may be a low-temperature polysilicon thin film transistor. A material of the first active layer 2011 is low-temperature polysilicon. The second transistor 202 may be an indium gallium zinc oxide thin film transistor. A material of the second active layer 2021 is an indium gallium zinc oxide. In other embodiments, the display substrate may be a low-temperature polysilicon display substrate, and a transistor of the display substrate may be a low-temperature polysilicon thin film transistor. The embodiments of the present disclosure do not limit types of the display substrates and types of the transistors.

In some exemplary embodiments, the first buffer layer 21, the first gate insulation layer 22, the second gate insulation layer 23, the first interlayer insulation layer 24, the third gate insulation layer 25, and the second interlayer insulation layer 26 may be inorganic insulation layers, and may adopt any one or more of silicon oxide (SiOx), silicon nitride (SiNx), and silicon oxynitride (SiOxNy), and may be a single layer structure or a multiple layer composite structure. The first planarization layer 27 and the second planarization layer 28 may be organic insulation layers, and may adopt resin materials. Materials of the first gate metal layer, the second gate metal layer, the third gate metal layer, the first source-drain metal layer, and the second source-drain metal layer may adopt any one or more of silver (Ag), copper (Cu), aluminum (Al), titanium (Ti), and molybdenum (Mo), or alloy materials of the above metals, such as an aluminum neodymium (AlNd) alloy or a molybdenum niobium (MoNb) alloy, and may be a single layer structure or a multiple layer composite structure, such as Mo/Cu/Mo and Ti/Al/Ti. The first semiconductor layer and the second semiconductor layer may adopt materials, such as amorphous indium gallium zinc oxide (a-IGZO) material, zinc oxynitride (ZnON), indium zinc tin oxide (IZTO), amorphous silicon (a-Si), polysilicon (p-Si), hexathiophene, or polythiophene.

In some exemplary embodiments, the base 10 may be a flexible base or may be a rigid base. The rigid base may be glass, quartz and the like. The flexible base may include one or more of polyethylene terephthalate, ethylene terephthalate, polyether ether ketone, polystyrene, polycarbonate, polyarylate, polyarylester, polyimide, polyvinyl chloride, polyethylene, and textile fiber.

In some exemplary embodiments, the first source-drain metal layer may include a first metal layer, a second metal layer, and a third metal layer sequentially disposed in a direction away from the base. The first metal layer and the third metal layer may be a titanium layer, and the second metal layer may be an aluminum layer. The second source-drain metal layer may include a fourth metal layer, a fifth metal layer, and a sixth metal layer sequentially disposed in a direction away from the base. The fourth metal layer and the sixth metal layer may be the titanium layer, and the fifth metal layer may be the aluminum layer. In other embodiments, the first source-drain metal layer and the second source-drain metal layer may be a single layer structure.

In some examples of the present embodiment, as shown in FIGS. 3 and 4, the isolation structure 50 may include at least one isolation undercut 51 disposed around the hole region. The isolation undercut 51 includes a groove 511 and a blocking edge 512 disposed on a side of the groove 511 away from the base 10. In a direction perpendicular to the base 10, the transition region 300 includes the first structure layer and the second structure layer sequentially stacked in a direction away from the base 10. The first structure layer includes the blocking layer 513. The groove 511 penetrates the second structure layer and exposes at least a portion of a surface of the blocking layer 513. The blocking edge 512 is disposed on a surface of the second structure layer away from the base 10, and a portion of the blocking edge 512 extends in a direction parallel to the base 10 and protrudes from a side wall of the groove 511.

Exemplarily, as shown in FIG. 3, the blocking layer 513 may be disposed in the same layer as the second active layer 2021 (the second semiconductor layer) of the second transistor 202. The second structure layer may include multiple inorganic insulation layers stacked, for example, may include a first inorganic insulation layer and a second inorganic insulation layer sequentially stacked in a direction away from the base 10. The first inorganic insulation layer is disposed in the same layer as the third gate insulation layer 25, and the second inorganic insulation layer is disposed in the same layer as the second interlayer insulation layer 26. The blocking edge 512 may be disposed in the same layer as the connection electrode 204.

Alternatively, as shown in FIG. 4, the blocking layer 513 may be disposed in the same layer as the first active layer 2011 (the first semiconductor layer) of the first transistor 201. The second structure layer may include multiple inorganic insulation layers stacked, for example, may include a first inorganic insulation layer, a second inorganic insulation layer, a third inorganic insulation layer, a fourth inorganic insulation layer, and a fifth inorganic insulation layer sequentially stacked in a direction away from the base 10. The first inorganic insulation layer is disposed in the same layer as the first gate insulation layer 22. The second inorganic insulation layer is disposed in the same layer as the second gate insulation layer 23. The third inorganic insulation layer is disposed in the same layer as the first interlayer insulation layer 24. The fourth inorganic insulation layer is disposed in the same layer as the third gate insulation layer 25. The fifth inorganic insulation layer is disposed in the same layer as the second interlayer insulation layer 26. The blocking edge 512 may be disposed in the same layer as the connection electrode 204.

In other embodiments, the blocking layer 513 may be disposed in the same layer as the first gate metal layer, the second gate metal layer, or the third gate metal layer. Alternatively, the blocking layer 513 may be an inorganic insulation layer, such as a SiOx layer. The second structure layer may include multiple inorganic insulation layers stacked. The blocking edge 512 may be disposed in the same layer as the connection electrode 204.

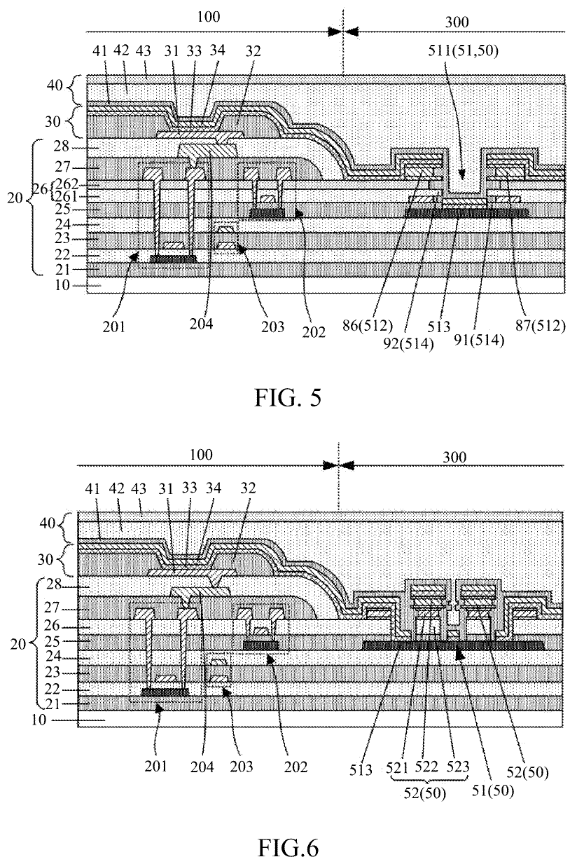

In some exemplary embodiments, as shown in FIG. 5, which is a schematic diagram of a cross-sectional structure taken along A-A of FIG. 1 according to some further exemplary embodiments, the isolation structure 50 may include at least one isolation undercut 51 disposed around the hole region. The isolation undercut 51 includes a groove 511 and a blocking edge 512 disposed on a side of the groove 511 away from the base 10. In a direction perpendicular to the base 10, the transition region 300 includes a first structure layer and a second structure layer sequentially stacked in a direction away from the base 10. The first structure layer includes the blocking layer 513. The groove 511 penetrates the second structure layer and exposes at least a portion of a surface of the blocking layer 513. The blocking edge 512 is disposed on a surface of the second structure layer away from the base 10, and a portion of the blocking edge 512 extends in a direction parallel to the base 10 and protrudes from a side wall of the groove 511.

Exemplarily, as shown in FIG. 5, the side wall of the groove 511 is provided with one or multiple protruding rings 514. The multiple protruding rings 514 are sequentially disposed in a direction perpendicular to the base 10. The groove 511 forms a trench between adjacent protruding rings 514, and forms the trench between the blocking edge 512 and the protruding rings 514. Exemplarily, a first protruding ring 91 and a second protruding ring 92 are sequentially disposed on the side wall of the groove 511 in a direction perpendicular to the base 10. In this embodiment, by disposing one or multiple protruding rings 514 on the side wall of the groove 511, the light-emitting functional layer 33 can be disconnected at a position of at least one protruding ring 514, and the isolation effect of the isolation undercut 51 can be improved. In addition, when an encapsulation layer of an inorganic material is subsequently deposited, the encapsulation material can have better climbing effect on the side wall of the groove 511, the encapsulation is denser, and the encapsulation effect is improved.

Exemplarily, as shown in FIG. 5, the blocking edge 512 may be disposed in the same layer as the connection electrode 204 (the second source-drain metal layer). Film layers of the blocking edge 512 may be the same as film layers of the connection electrode 204. The second source-drain metal layer may be a single layer structure or a multiple layer structure, and then the blocking edge 512 and the connection electrode 204 may be the single layer structure or the multiple layer structure. Exemplarily, the second source-drain metal layer may include a fourth metal layer, a fifth metal layer, and a sixth metal layer sequentially disposed in a direction away from the base 10. The fourth metal layer and the sixth metal layer may be a titanium layer, and the fifth metal layer may be an aluminum layer. Then, the blocking edge 512 and the connection electrode 204 each include a fourth metal layer, a fifth metal layer, and a sixth metal layer sequentially disposed in the direction away from the base 10. The fifth metal layer may be recessed inward relative to the fourth metal layer and the sixth metal layer (i.e., the fourth metal layer and the sixth metal layer are disposed protruding from the fifth metal layer) on a side of the blocking edge 512 close to the groove 511.

Exemplarily, as shown in FIG. 5, the second interlayer insulation layer 26 may include a first sublayer 261 and a second sublayer 262 sequentially disposed in a direction away from the base 10. A material of the first sublayer 261 may be silicon oxide, and a material of the second sublayer 262 may be silicon nitride. At least one protruding ring 514 may be disposed in the same layer as the first sublayer 261 and have the same material as the first sublayer 261.

Exemplarily, as shown in FIG. 5, the blocking layer 513 may be disposed in the same layer as the second active layer 2021 of the second transistor 202. In other embodiments, the blocking layer 513 may be disposed in the same layer as the first active layer 2011, the first gate metal layer, the second gate metal layer, or the third gate metal layer of the first transistor 201.

Exemplarily, as shown in FIG. 5, the second structure layer may include at least one inorganic insulation layer and at least one metal layer. A metal layer in the second structure layer may be disposed in the same layer as the third gate metal layer. The protruding ring 514 may be formed of an inorganic insulation layer in the second structure layer. In other embodiments, any of the metal layers in the second structure layer may be disposed in the same layer as the third gate metal layer, the second gate metal layer, or the first gate metal layer.

In some exemplary embodiments, as shown in FIG. 6, which is a schematic diagram of a cross-sectional structure taken along A-A of FIG. 1 according to some further exemplary embodiments, the isolation structure 50 may include at least one isolation column 52 disposed around the hole region. The isolation column 52 may include a first isolation portion 521 and a second isolation portion 522 sequentially disposed in a direction away from the base 10. The second isolation portion 522 is disposed protruding from the first isolation portion 521 on a side of the isolation column 52 facing the display region 100 or/and the hole region 200.

Exemplarily, as shown in FIG. 6, materials of the first isolation portion 521 and the second isolation portion 522 each may be metal materials. The first isolation portion 521 may include a first metal layer, a second metal layer, and a third metal layer sequentially disposed in a direction away from the base 10. On a side of the isolation column 52 facing the display region 100 or/and the hole region 200, the second metal layer is recessed inward relative to the first metal layer and the third metal layer. Or/and, the second isolation portion 522 may include a fourth metal layer, a fifth metal layer, and a sixth metal layer sequentially disposed in the direction away from the base 10. On the side of the isolation column 52 facing the display region 100 or/and the hole region 200, the fifth metal layer is recessed inward relative to the fourth metal layer and the sixth metal layer. Compared with some technologies in which the isolation column 52 only includes the first isolation portion 521 or the second isolation portion 522, the isolation column 52 of the present example can improve the isolation effect of the isolation column 52 and can improve the strength of the isolation column 52 by providing the first isolation portion 521 and the second isolation portion 522.

The fourth metal layer may be disposed on a surface of the third metal layer away from the base 10. On the side of the isolation column 52 facing the display region 100 or/and the hole region 200, the fourth metal layer may be disposed protruding from the third metal layer.

The first isolation portion 521 may be disposed in the same layer as the first source electrode and the first drain electrode (the same layer as the first source-drain metal layer). The second isolation portion 522 may be disposed in the same layer as the connection electrode 204 (the second source-drain metal layer). The first metal layer and the third metal layer of the first isolation portion 521 may be a titanium layer, and the second metal layer may be an aluminum layer. The fourth metal layer and the sixth metal layer of the second isolation portion 522 may be a titanium layer, and the fifth metal layer may be an aluminum layer.

Exemplarily, as shown in FIG. 6, the isolation column 52 may further include a column base 523 disposed on a side of the first isolation portion 521 facing the base 10. The column base 523 may include at least one inorganic insulation layer. For example, the column base 523 may include multiple inorganic insulation layers stacked, or the column base 523 may include at least one inorganic insulation layer and at least one metal layer, and the metal layer in the column base 523 may be wrapped with the inorganic insulation layer in the column base 523.

Exemplarily, as shown in FIG. 6, the transition region 300 is further provided with a blocking layer 513. The isolation column 52 is disposed on a surface of the blocking layer 513 away from the base 10. The blocking layer 513 may be disposed in the same layer as the first active layer 2011, the first gate electrode 2012, any one of the electrode plates of the storage capacitor 203, the second active layer 2021, or the second gate electrode 2022.

Exemplarily, as shown in FIG. 6, the isolation structure 50 may include multiple isolation columns 52. One isolation undercut 51 is formed between two adjacent isolation columns 52. Similarly, the isolation structure 50 may include multiple isolation undercuts 51. One isolation column 52 may be formed between two adjacent isolation undercuts 51.

A structure of the display substrate will be described illustratively below through a preparation process of the display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and ink jet printing, and etching may be any one or more of dry etching and wet etching, the present disclosure is not limited thereto. A “thin film” refers to a layer of thin film made of a certain material on a base using deposition, coating, or other processes. If the “thin film” does not need to be processed through a patterning process in the entire preparation process, the “thin film” may also be called a “layer”. If the “thin film” needs to be processed through the patterning process in the entire preparation process, the “thin film” is called a “thin film” before the patterning process is performed and is called a “layer” after the patterning process is performed. At least one “pattern” is contained in the “layer” which has been processed through the patterning process. A “thickness” of a film layer is a dimension of the film layer in a direction perpendicular to the display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In some exemplary embodiments, taking the display substrate illustrated in FIG. 3 as an example, a preparation process of the display substrate may, for example, include the following operations.

(1) Forming a drive structure layer 20 and film layers of an isolation undercut 51.

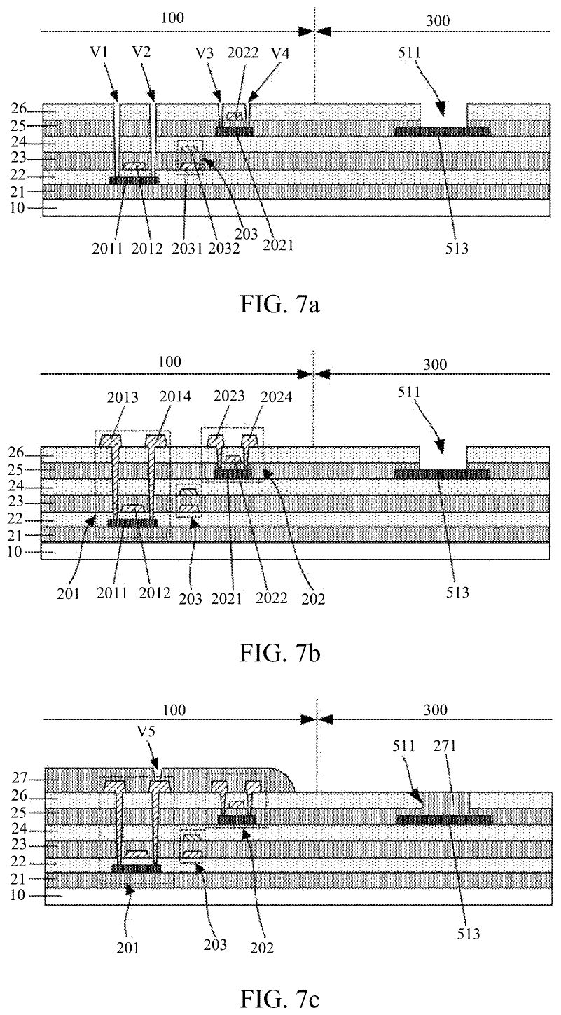

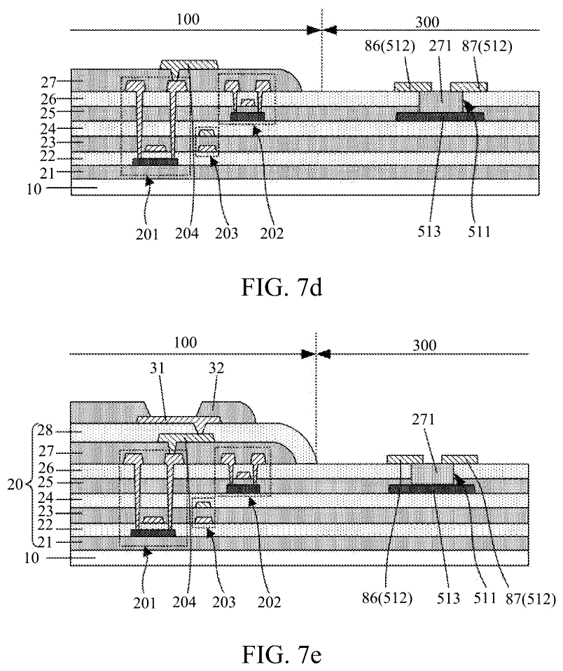

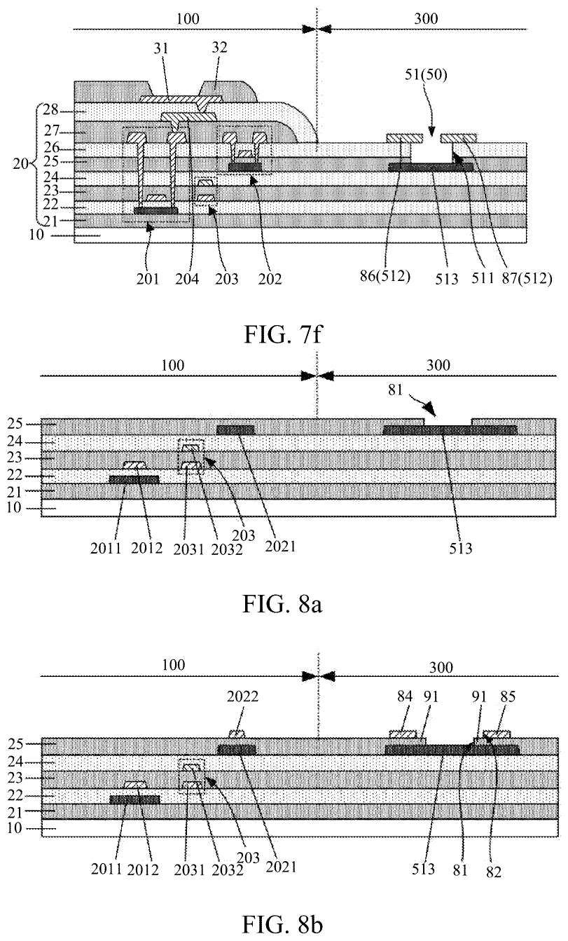

A first buffer thin film and a first semiconductor thin film are sequentially deposited on a base 10, and the first semiconductor thin film is patterned by a patterning process to form a first buffer layer 21 covering the base 10 and a pattern of the first semiconductor layer disposed on the first buffer layer 21. The pattern of the first semiconductor layer includes multiple first active layers 2011 located in a display region 100. After this patterning process, a transition region 300 includes the first buffer layer 21 disposed on the base 10, as shown in FIG. 7a.

Subsequently, a first gate insulation thin film and a first gate metal thin film are sequentially deposited, and the first gate metal thin film is patterned by a patterning process to form a first gate insulation layer 22 covering the pattern of the first semiconductor layer and a pattern of a first gate metal layer disposed on the first gate insulation layer 22. The pattern of the first gate metal layer includes multiple first gate electrodes 2012 and multiple first electrode plates 2031 located in the display region 100. After this patterning process, the transition region 300 includes the first buffer layer 21 and the first gate insulation layer 22 sequentially stacked on the base 10, as shown in FIG. 7a.

Subsequently, a second gate insulation thin film and a second gate metal thin film are sequentially deposited, and the second gate metal thin film is patterned by a patterning process to form a second gate insulation layer 23 covering the pattern of the first gate metal layer and a pattern of a second gate metal layer disposed on the second gate insulation layer 23. The pattern of the second gate metal layer includes multiple second electrode plates 2032 located in the display region 100. The multiple second electrode plates 2032 and the multiple first electrode plates 2031 are disposed opposite to each other and form multiple storage capacitors 203. After this patterning process, the transition region 300 includes the first buffer layer 21, the first gate insulation layer 22 and the second gate insulation layer 23 sequentially stacked on the base 10, as shown in FIG. 7a.

Subsequently, a first interlayer insulation thin film and a second semiconductor thin film are deposited, and the second semiconductor thin film is patterned by a patterning process to form a first interlayer insulation layer 24 covering the pattern of the second gate metal layer and a pattern of a second semiconductor layer disposed on the first interlayer insulation layer 24. The pattern of the second semiconductor layer includes multiple second active layers 2021 located in the display region 100 and a blocking layer 513 located in the transition region 300. After this patterning process, the transition region 300 includes the first buffer layer 21, the first gate insulation layer 22, the second gate insulation layer 23, the first interlayer insulation layer 24, and the blocking layer 513 disposed on the first interlayer insulation layer 24, which are sequentially stacked on the base 10, as shown in FIG. 7a.

Subsequently, a third gate insulation thin film and a third gate metal thin film are sequentially deposited, and the third gate metal thin film is patterned by a patterning process to form a third gate insulation layer 25 covering the pattern of the second semiconductor layer and a pattern of a third gate metal layer disposed on the third gate insulation layer 25. The pattern of the third gate metal layer includes multiple second gate electrodes 2022 located in the display region 100. After this patterning process, the transition region 300 includes the first buffer layer 21, the first gate insulation layer 22, the second gate insulation layer 23, the first interlayer insulation layer 24, the blocking layer 513, and the third gate insulation layer 25 covering the blocking layer 513, which are sequentially stacked on the base 10, as shown in FIG. 7a.

Subsequently, a second interlayer insulation thin film is deposited, and the second interlayer insulation thin film is patterned by a patterning process to form a pattern of a second interlayer insulation layer 26 covering the pattern of the third gate metal layer. The second interlayer insulation layer 26 of the display region 100 is provided with multiple first via holes V1, multiple second via holes V2, multiple third via holes V3, and multiple fourth via holes V4. The multiple first via holes V1 expose one end of the multiple first active layers 2011, and the multiple second via holes V2 expose the other end of the multiple first active layers 2011. The multiple third via holes V3 expose one end of the multiple second active layers 2021, and the multiple fourth via holes V4 expose the other end of the multiple second active layers 2021. The second interlayer insulation layer 26 of the transition region 300 is provided with a groove 511 that penetrates the third gate insulation layer 25 and exposes the blocking layer 513. After this patterning process, the transition region 300 includes the first buffer layer 21, the first gate insulation layer 22, the second gate insulation layer 23, the first interlayer insulation layer 24, the blocking layer 513, the third gate insulation layer 25 covering the blocking layer 513, and the second interlayer insulation layer 26 disposed on the third gate insulation layer 25, which are sequentially stacked on the base 10. The second interlayer insulation layer 26 of the transition region 300 is provided with the groove 511 that penetrates the third gate insulation layer 25 and exposes the blocking layer 513, as shown in FIG. 7a.

Subsequently, a first source-drain metal thin film is deposited, and the first source-drain metal thin film is patterned by a patterning process to form a pattern of a first source-drain metal layer on the second interlayer insulation layer 26. The pattern of the first source-drain metal layer includes multiple first source electrodes 2013, multiple first drain electrodes 2014, multiple second source electrodes 2023, and multiple second drain electrodes 2024 located in the display region 100. The first source electrode 2013 is connected to one end of the first active layer 2011 through the first via hole V1. The first drain electrode 2014 is connected to the other end of the first active layer 2011 through the second via hole V2. The second source electrode 2023 is connected to one end of the second active layer 2021 through the third via hole V3. The second drain electrode 2024 is connected to the other end of the second active layer 2021 through the fourth via hole V4. The multiple first active layers 2011, the multiple first gate electrodes 2012, the multiple first source electrodes 2013, and the multiple first drain electrodes 2014 of the display region 100 form multiple first transistors 201. The multiple second active layers 2021, the multiple second gate electrodes 2022, the multiple second source electrodes 2023, and the multiple second drain electrodes 2024 form multiple second transistors 202. As shown in FIG. 7b, one first transistor 201 and one second transistor 202 are illustrated in FIG. 7b.

The first source-drain metal layer may include a first metal layer, a second metal layer, and a third metal layer sequentially stacked in a direction away from the base 10. For example, the first metal layer and the third metal layer may be a titanium layer, and the second metal layer may be an aluminum layer. Then, the first source electrode 2013, the first drain electrode 2014, the second source electrode 2023, and the second drain electrode 2024 each include the first metal layer, the second metal layer, and the third metal layer sequentially stacked in a direction away from the base 10.

Subsequently, a first planarization thin film is coated, and the first planarization thin film is patterned by a patterning process to form a pattern of a first planarization layer 27 covering the pattern of the first source-drain metal layer. The first planarization layer 27 is provided with a fifth via hole V5 in the display region 100, and the first planarization layer 27 in the fifth via hole V5 is removed and a surface of the first source electrode 2013 or the first drain electrode 2014 is exposed. The pattern of the first planarization layer 27 includes a filling layer 271 located in the transition region 300 and filled in the groove 511, and the filling layer 271 can fill and level up the groove 511, as shown in FIG. 7c.

Subsequently, a second source-drain metal thin film is deposited, and the second source-drain metal thin film is patterned by a patterning process to form a pattern of a second source-drain metal layer on the first planarization layer 27. The pattern of the second source-drain metal layer includes multiple anode connection electrodes 204 located in the display region 100, and multiple blocking edges 512 located in the transition region 300. The anode connection electrode 204 is connected to the first source electrode 2013 or the first drain electrode 2014 through the fifth via hole V5. The multiple blocking edges 512 may include a first blocking edge 86 and a second blocking edge 87. The first blocking edge 86 is located on the second interlayer insulation layer 26 on a side of the groove 511 facing the display region 100 and a portion of the first blocking edge 86 is located on the filling layer 271. The second blocking edge 87 is located on the second interlayer insulation layer 26 on a side of the groove 511 facing the hole region and a portion of the second blocking edge 87 is located on the filling layer 271. A distance between the first blocking edge 86 and the second blocking edge 87 in a direction parallel to the base 10 is smaller than a width of a notch of the groove 511, as shown in FIG. 7d.

A film layer structure and a material of the second source-drain metal layer may be the same as a film layer structure and a material of the first source-drain metal layer. For example, the second source-drain metal layer may include a fourth metal layer, a fifth metal layer, and a sixth metal layer sequentially stacked in a direction away from the base 10. For example, the fourth metal layer and the sixth metal layer may be a titanium layer, and the fifth metal layer may be an aluminum layer.

Subsequently, a second planarization thin film is coated, and the second planarization thin film is patterned by a patterning process to form a pattern of a second planarization layer 28 covering the pattern of the second source-drain metal layer of the display region 100. The second planarization layer 28 exposes multiple blocking edges 512 of the transition region 300 and the filling layer 271 in the groove 511. The second planarization layer 28 is formed with multiple sixth via holes located in the display region 100, and the second planarization layer 28 in the sixth via holes is removed and a surface of the anode connection electrode 204 is exposed, as shown in FIG. 7e.

Hereto, the preparation of the drive structure layer 20 and the film layers of the isolation undercut 51 is completed.

(2) Forming a light-emitting structure layer 30. In an exemplary embodiment, forming the light-emitting structure layer 30 may include the following operations.

A first electrode 31 thin film is deposited on the base 10 on which the aforementioned patterns are formed. The first electrode 31 thin film is patterned by a patterning process to form a pattern of a first electrode layer. The pattern of the first electrode layer includes multiple first electrodes 31 (anodes) located in the display region 100. The first electrode 31 is connected to the anode connection electrode 204 through the sixth via hole on the second planarization layer 28, so that the first electrode 31 is connected to the first source electrode 2013 or the first drain electrode 2014 through the anode connection electrode 204, as shown in FIG. 7e.

Subsequently, a pixel definition thin film is coated on the base 10 on which the aforementioned patterns are formed. The pixel definition thin film is patterned by a patterning process to form a pattern of a pixel definition layer 32. The pixel definition layer 32 is provided with multiple pixel openings exposing a surface of the first electrode 31 of the display region 100, as shown in FIG. 7e.

Subsequently, the filling layer 271 in the groove 511 is etched and removed by an etching process. Exemplarily, oxygen etching may be employed, as shown in FIG. 7f.

Subsequently, on the base 10 on which the aforementioned patterns are formed, multiple film layers of a light-emitting functional layer 33 may be sequentially formed by an evaporation process. The light-emitting functional layer 33 may include a hole injection layer, a hole transporting layer, an electron blocking layer, an organic light-emitting layer, a hole blocking layer, an electron transporting layer, and an electron injection layer, which are sequentially disposed in a direction away from the base 10. Except for the organic light-emitting layer, the remaining film layers of the light-emitting functional layer 33 may have an integrated monolithic structure. That is, the remaining film layers of the light-emitting functional layer 33 may be common layers for sub-pixels having different colors, and these common layers may be formed in the display region 100 and the transition region 300 during evaporation. Due to isolation undercut 51 provided in the transition region 300, these common layers are disconnected at the isolation undercut 51, blocking a transmission path of water and oxygen from the hole region 200 to the display region 100 through the light-emitting functional layer 33, and preventing water and oxygen from eroding the light-emitting functional layer 33 of the display region 100, as shown in FIG. 3.

Subsequently, on the base 10 on which the aforementioned patterns are formed, a second electrode (cathode) layer is formed by an evaporation process. The second electrode layer 34 of sub-pixels having different colors is a common layer connected as an integrated structure. The second electrode layer 34 may be formed in the display region 100 and the transition region 300. The second electrode layer 34 may be disconnected at the isolation undercut 51, blocking the transmission path of water and oxygen from the hole region 200 to the display region 100 through the second electrode layer 34, and preventing water and oxygen from eroding the second electrode layer 34 of the display region 100, as shown in FIG. 3.

Hereto, the preparation of the light-emitting structure layer 30 is completed.

(3) Forming an encapsulation structure layer 40. In an exemplary embodiment, forming the encapsulation structure layer 40 may include the following operations.

On the base 10 on which the aforementioned patterns are formed, a first encapsulation thin film is first deposited using an open mask by a deposition method to form a first encapsulation layer 41 located in the display region 100 and the transition region 300. Subsequently, a second encapsulation material is printed using an open mask by an ink jet printing process to form a second encapsulation layer 42 located in the display region 100 and the transition region 300. An isolation dam 60 of the transition region 300 may block ink overflow during the ink jet printing process. Subsequently, a third encapsulation thin film is deposited using an open mask by the deposition method to form a third encapsulation layer 43 located in the display region 100 and the transition region 300. Materials of the first encapsulation layer 41 and the third encapsulation layer 43 may be an inorganic material, and a material of the second encapsulation layer 42 may be an organic material, as shown in FIG. 3.

Subsequently, film layers such as a touch structure layer and a color film layer may be sequentially formed on a side of the encapsulation structure layer 40 away from the base 10.

In other exemplary embodiments, taking a display substrate illustrated in FIG. 5 as an example, a preparation process of the display substrate may, for example, include the following operations.

(1) Forming a drive structure layer 20 and film layers of an isolation undercut 51.

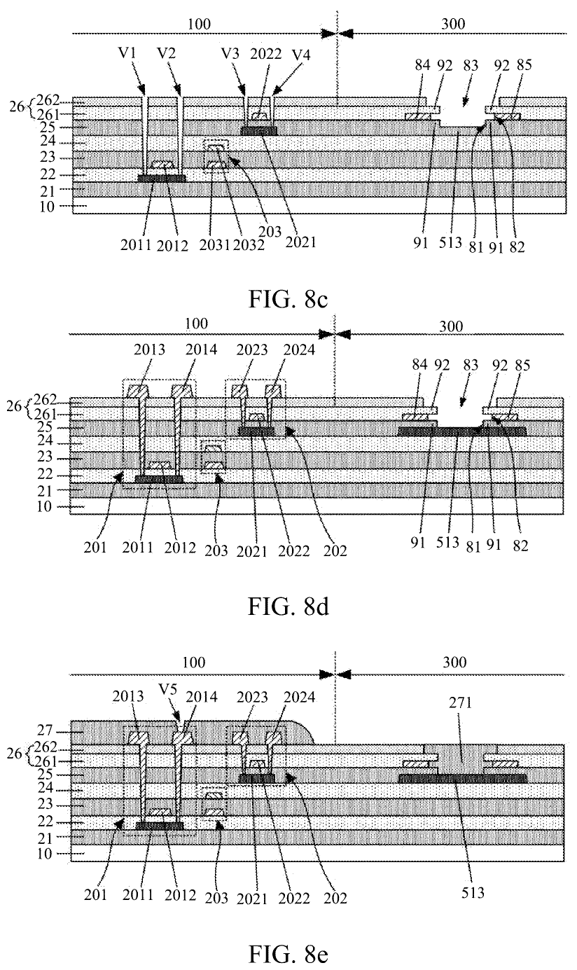

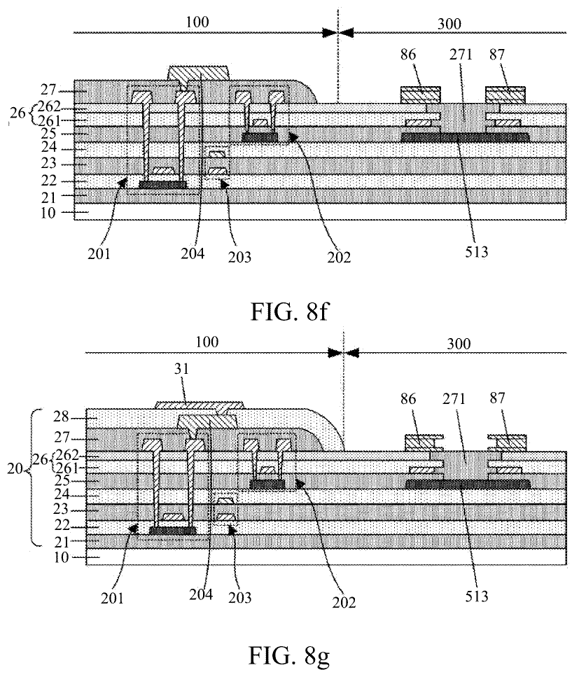

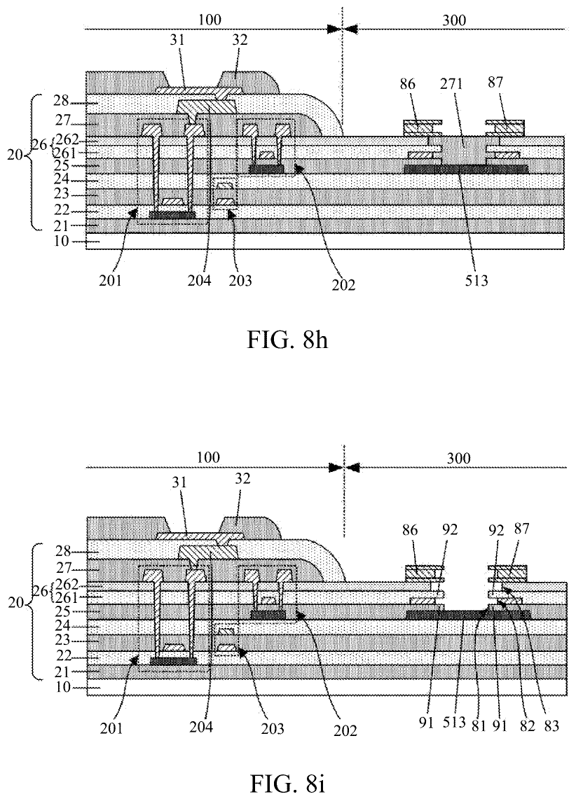

A first buffer thin film and a first semiconductor thin film are sequentially deposited on a base 10, and the first semiconductor thin film is patterned by a patterning process to form a first buffer layer 21 covering the base 10, and a pattern of a first semiconductor layer disposed on the first buffer layer 21. The pattern of the first semiconductor layer includes multiple active layers 2011 located in a display region 100. After this patterning process, a transition region 300 includes the first buffer layer 21 disposed on the base 10, as shown in FIG. 8a.

Subsequently, a first gate insulation thin film and a first gate metal thin film are sequentially deposited, and the first gate metal thin film is patterned by a patterning process to form a first gate insulation layer 22 covering the pattern of the first semiconductor layer, and a pattern of a first gate metal layer disposed on the first gate insulation layer 22. The pattern of the first gate metal layer includes multiple first gate electrodes 2012 and multiple first electrode plates 2031 located in the display region 100. After this patterning process, the transition region 300 includes the first buffer layer 21 and the first gate insulation layer 22 sequentially stacked on the base 10, as shown in FIG. 8a.

Subsequently, a second gate insulation thin film and a second gate metal thin film are sequentially deposited, and the second gate metal thin film is patterned by a patterning process to form a second gate insulation layer 23 covering the pattern of the first gate metal layer, and a pattern of a second gate metal layer disposed on the second gate insulation layer 23. The pattern of the second gate metal layer includes multiple second electrode plates 2032 located in the display region 100. The multiple second electrode plates 2032 and the multiple first electrode plates 2031 are disposed opposite to each other and form multiple storage capacitors 203. After this patterning process, the transition region 300 includes the first buffer layer 21, the first gate insulation layer 22 and the second gate insulation layer 23 sequentially stacked on the base 10, as shown in FIG. 8a.

Subsequently, a first interlayer insulation thin film and a second semiconductor thin film are deposited, and the second semiconductor thin film is patterned by a patterning process to form a first interlayer insulation layer 24 covering a pattern of a second gate metal layer, and a pattern of a second semiconductor layer disposed on the first interlayer insulation layer 24. The pattern of the second semiconductor layer includes multiple second active layers 2021 located in the display region 100 and a blocking layer 513 located in the transition region 300. After this patterning process, the transition region 300 includes the first buffer layer 21, the first gate insulation layer 22, the second gate insulation layer 23, the first interlayer insulation layer 24, and the blocking layer 513 disposed on the first interlayer insulation layer 24, which are sequentially stacked on the base 10, as shown in FIG. 8a.

Subsequently, a third gate insulation thin film is sequentially deposited, and the third gate insulation thin film is patterned by a patterning process to form a pattern of a third gate insulation layer 25 covering the pattern of the second semiconductor layer. The third gate insulation layer 25 of the transition region 300 is provided with a first groove 81 surrounding the hole region 200. The first groove 81 exposes at least partially the blocking layer 513, as shown in FIG. 8a.

Subsequently, a third gate metal thin film is deposited, and the third gate metal thin film is patterned by a patterning process to form a pattern of a third gate metal layer located on the third gate insulation layer 25. The pattern of the third gate metal layer includes multiple second gate electrodes 2022 located in the display region 100, and a first metal ring 84 and a second metal ring 85 located in the transition region 300. The first metal ring 84 and the second metal ring 85 each are located on a side of the first groove 81 close to the display region 100 and a side of the first groove 81 close to the hole region 200. Edges of the first metal ring 84 and the second metal ring 85 close to the first groove 81 are recessed inward relative to a side wall of the first groove 81. A portion of the third gate insulation layer 25 protruding from the edge of the first metal ring 84 close to the first groove 81 forms a first protruding ring 91, and a portion of the third gate insulation layer 25 protruding from the edge of the second metal ring 85 close to the first groove 81 forms another first protruding ring 91. A second groove 82 is formed between the first metal ring 84 and the second metal ring 85, as shown in FIG. 8b.

Subsequently, a second interlayer insulation thin film is deposited, and the second interlayer insulation thin film is patterned by a patterning process to form a pattern of a second interlayer insulation layer 26 covering the pattern of third gate metal layer. The second interlayer insulation layer 26 may include a first sublayer 261 and a second sublayer 262 sequentially stacked in a direction away from the base 10. A material of the first sublayer 261 may be silicon oxide, and a material of the second sublayer 262 may be silicon nitride. The second interlayer insulation layer 26 of the display region 100 is provided with multiple first via holes V1, multiple second via holes V2, multiple third via holes V3, and multiple fourth via holes V4. The multiple first via holes V1 expose one end of the multiple first active layers 2011, and the multiple second via holes V2 expose the other end of the multiple first active layers 2011. The multiple third via holes V3 expose one end of the multiple second active layers 2021, and the multiple fourth via holes V4 expose the other end of the multiple second active layers 2021. The second interlayer insulation layer 26 of the transition region 300 is provided with a third groove 83 exposing the first groove 81 and the second groove 82. The first sublayer 261 is disposed protruding from the second sublayer 262 on a side wall of the third groove 83 (the selection ratio of an etching solution or an etching gas to the first sublayer 261 and the second sublayer 262 is different during the etching process, and thus, a stepped side wall of the third groove 83 can be formed). On a side wall of the third groove 83 close to the display region 100, a portion of the first sublayer 261 protruding from the second sublayer 262 forms a second protruding ring 92, and on a side wall of the third groove 83 close to the hole region 200, a portion of the first sublayer 261 protruding from the second sublayer 262 forms another second protruding ring 92. Two second protruding rings 92 are also disposed protruding from the first metal ring 84 and the second metal ring 85, respectively, as shown in FIG. 8c.

Subsequently, a first source-drain metal thin film is deposited, and the first source-drain metal thin film is patterned by a patterning process to form a pattern of a first source-drain metal layer on the second interlayer insulation layer 26. The pattern of the first source-drain metal layer includes multiple first source electrodes 2013, multiple first drain electrodes 2014, multiple second source electrodes 2023 and multiple second drain electrodes 2024 located in the display region 100. The first source electrode 2013 is connected to one end of the first active layer 2011 through the first via hole V1. The first drain electrode 2014 is connected to the other end of the first active layer 2011 through the second via hole V2. The second source electrode 2023 is connected to one end of the second active layer 2021 through the third via hole V3. The second drain electrode 2024 is connected to the other end of the second active layer 2021 through the fourth via hole V4. The multiple first active layers 2011, the multiple first gate electrodes 2012, the multiple first source electrodes 2013, and the multiple first drain electrodes 2014 of the display region 100 form multiple first transistors 201. The multiple second active layers 2021, the multiple second gate electrodes 2022, the multiple second source electrodes 2023, and the multiple second drain electrodes 2024 form multiple second transistors 202. As shown in FIG. 8d, one first transistor 201 and one second transistor 202 are illustrated in FIG. 8d.

The first source-drain metal layer may include a first metal layer, a second metal layer, and a third metal layer sequentially stacked in a direction away from the base 10. For example, the first metal layer and the third metal layer may be a titanium layer, and the second metal layer may be an aluminum layer. Then, the first source electrode 2013, the first drain electrode 2014, the second source electrode 2023, and the second drain electrode 2024 each include the first metal layer, the second metal layer, and the third metal layer sequentially stacked in a direction away from the base 10.

Subsequently, a first planarization thin film is coated, and the first planarization thin film is patterned by a patterning process to form a pattern of a first planarization layer 27 covering the pattern of the first source-drain metal layer. The first planarization layer 27 is provided with a fifth via hole V5 in the display region 100, and the first planarization layer 27 in the fifth via hole V5 is removed and a surface of the first source electrode 2013 or the first drain electrode 2014 is exposed. The pattern of the first planarization layer 27 includes a filling layer 271 located in the transition region 300 and filled in the third groove 83, the second groove 82 and the first groove 81. The filling layer 271 can fill and level up the third groove 83, as shown in FIG. 8e.

Subsequently, a second source-drain metal thin film is deposited, and the second source-drain metal thin film is patterned by a patterning process to form a pattern of a second source-drain metal layer on the first planarization layer 27. The pattern of the second source-drain metal layer includes multiple anode connection electrodes 204 located in the display region 100, and a first blocking edge 86 and a second blocking edge 87 located in the transition region 300. The anode connection electrode 204 is connected to the first source electrode 2013 or the first drain electrode 2014 through the fifth via hole V5. The first blocking edge 86 and the second blocking edge 87 are located on a side of the third groove 83 close to the display region 100 and a side close to the hole region 200, respectively. Bothe portions of the first blocking edge 86 and the second blocking edge 87 are located on the second interlayer insulation layer 26 and the other portions of the first blocking edge 86 and the second blocking edge 87 are located on the filling layer 271. The third groove 83, the second groove 82 and the first groove 81 form the groove 511 of the isolation undercut 51. The first blocking edge 86 and the second blocking edge 87 each are partially located above the groove 511 (i.e., a side of the groove 511 away from the base 10), as shown in FIG. 8f.

A film layer structure and a material of the second source-drain metal layer may be the same as a film layer structure and a material of the first source-drain metal layer. For example, the second source-drain metal layer may include a fourth metal layer, a fifth metal layer, and a sixth metal layer sequentially stacked in a direction away from the base 10. For example, the fourth metal layer and the sixth metal layer may be a titanium layer, and the fifth metal layer may be an aluminum layer. Then, the connection electrode 204, the first blocking edge 86, and the second blocking edge 87 each include a fourth metal layer, a fifth metal layer, and a sixth metal layer sequentially stacked in a direction away from the base 10, as shown in FIG. 8f.

Subsequently, a second planarization thin film is coated, and the second planarization thin film is patterned by a patterning process to form a pattern of a second planarization layer 28 covering the pattern of the second source-drain metal layer of the display region 100. The second planarization layer 28 is formed with multiple sixth via holes located in the display region 100. The second planarization layer 28 in the sixth via hole is removed and a surface of the anode connection electrode 204 is exposed, as shown in FIG. 8g.

Hereto, the preparation of the drive structure layer 20 and the film layers of the isolation undercut 51 is completed.

(2) Forming a light-emitting structure layer 30. In an exemplary embodiment, forming the light-emitting structure layer 30 may include the following operations.

A first electrode 31 thin film is deposited on the base 10 on which the aforementioned patterns are formed, and the first electrode 31 thin film is patterned by a patterning process to form a pattern of a first electrode layer. The pattern of the first electrode layer includes multiple first electrodes 31 (anodes) located in the display region 100. The first electrode 31 is connected to the anode connection electrodes 204 through the sixth via holes on the second planarization layer 28, so that the first electrode 31 is connected to the first source electrode 2013 or the first drain electrodes 2014 through the anode connection electrodes 204, as shown in FIG. 8g.

During a patterning process (such as a wet etching process) of the first electrode 31 thin film, the fifth metal layer of the first blocking edge 86 and the second blocking edge 87 may be laterally etched simultaneously so that on sides of the first blocking edge 86 and the second blocking edge 87 close to the groove 511 of the isolation undercut 51, the fifth metal layer of the first blocking edge 86 and second blocking edge 87 is partially recessed inward relative to the fourth metal layer and sixth metal layer (i.e., the fourth metal layer and sixth metal layer protruding relative to the fifth metal layer), as shown in FIG. 8g. In other embodiments, the fifth metal layers of the first blocking edge 86 and second blocking edge 87 may be laterally etched simultaneously during the aforementioned patterning process (such as a development process) of the second planarization thin film, such that on sides of the first blocking edge 86 and second blocking edge 87 close to the groove 511 of the isolation undercut 51, the fifth metal layers of the first blocking edge 86 and the second blocking edge 87 are partially recessed inward relative to the fourth metal layer and sixth metal layer.

Subsequently, a pixel definition thin film is coated on the base 10 on which the aforementioned patterns are formed, and the pixel definition thin film is patterned by a patterning process to form a pattern of a pixel definition layer 32. The pixel definition layer 32 is provided with multiple pixel openings exposing a surface of the first electrode 31 of the display region 100, as shown in FIG. 8h.

Subsequently, the filling layer 271 in the groove 511 of the isolation undercut 51 is etched and removed by an etching process (dry etching or wet etching, such as etching with oxygen gas), as shown in FIG. 8i. Thereto, the structure of the isolation undercut 51 is formed.

Subsequently, on the base 10 on which the aforementioned patterns are formed, multiple film layers of a light-emitting functional layer 33 may be sequentially formed by an evaporation process. The light-emitting functional layer 33 may include a hole injection layer, a hole transporting layer, an electron blocking layer, an organic light-emitting layer, a hole blocking layer, an electron transporting layer, and an electron injection layer, which are sequentially disposed in a direction away from the base 10. Except for the organic light-emitting layer, the remaining film layers of the light-emitting functional layer 33 may have an integrated monolithic structure. That is, the remaining film layers of the light-emitting functional layer 33 may be common layers for sub-pixels having different colors, and these common layers may be formed in the display region 100 and the transition region 300 at the time of evaporation. Due to the isolation undercut 51 disposed in the transition region 300, these common layers are disconnected at the isolation undercut 51, blocking the transmission path of water and oxygen from the hole region 200 to the display region 100 through the light-emitting functional layer 33, and preventing water and oxygen from eroding the light-emitting functional layer 33 of the display region 100, as shown in FIG. 5.

Subsequently, on the base 10 on which the aforementioned patterns are formed, a second electrode (cathode) layer is formed by an evaporation process. The second electrode layer 34 of sub-pixels having different colors is a common layer connected as an integrated structure, and the second electrode layer 34 may be formed in the display region 100 and the transition region 300. The second electrode layer 34 may be disconnected at the isolation undercut 51, blocking the transmission path of water and oxygen from the hole region 200 to the display region 100 through the second electrode layer 34, and preventing water and oxygen from eroding the second electrode layer 34 of the display region 100, as shown in FIG. 5.

Hereto, the preparation of the light-emitting structure layer 30 is completed.

(3) Forming an encapsulation structure layer 40. In an exemplary embodiment, forming the encapsulation structure layer 40 may include the following operations.

On the base 10 on which the aforementioned patterns are formed, a first encapsulation thin film is first deposited using an open mask by a deposition method to form a first encapsulation layer 41 located in the display region 100 and the transition region 300. Subsequently, a second encapsulation material is printed using an open mask by an ink jet printing process to form a second encapsulation layer 42 located in the display region 100 and the transition region 300. The isolation dam 60 of the transition region 300 may block ink overflow during the ink jet printing process. Subsequently, a third encapsulation thin film is deposited using an open mask by a deposition method to form a third encapsulation layer 43 located in the display region 100 and the transition region 300. Materials of the first encapsulation layer 41 and the third encapsulation layer 43 may be an inorganic material, and a material of the second encapsulation layer 42 may be an organic material, as shown in FIG. 5.

Subsequently, film layers such as a touch structure layer and a color film layer may be sequentially formed on a side of the encapsulation structure layer 40 away from the base 10.

Based on the preparation methods of the display substrate illustrated in FIGS. 3 and 5, an embodiment of the present disclosure further provides a method of preparing the display substrate illustrated in FIGS. 3 and 5, including: sequentially forming a first structure layer and a second structure layer on a base of a transition region, the first structure layer including a blocking layer, the second structure layer being provided with a groove, the groove penetrating the second structure layer and exposing at least a portion of a surface of the blocking layer; forming a filling layer within the groove, the filling layer filling and leveling up the groove; forming a blocking edge on a surface of the second structure layer away from the base, a portion of the blocking edge extending onto a surface of the filling layer away from the base in a direction parallel to the base; and removing the filling layer.

In some exemplary embodiments, the blocking edge includes a fourth metal layer, a fifth metal layer, and a sixth metal layer sequentially stacked in a direction away from the base. The method further includes etching the fifth metal layer of the blocking edge such that the fifth metal layer is recessed inward relative to the fourth metal layer and the sixth metal layer on a side of the blocking edge close to the groove.

In some further exemplary embodiments, taking a display substrate illustrated in FIG. 6 as an example, a preparation process of the display substrate may, for example, include the following operations:

(1) Forming a drive structure layer 20 and film layers of an isolation column 52.

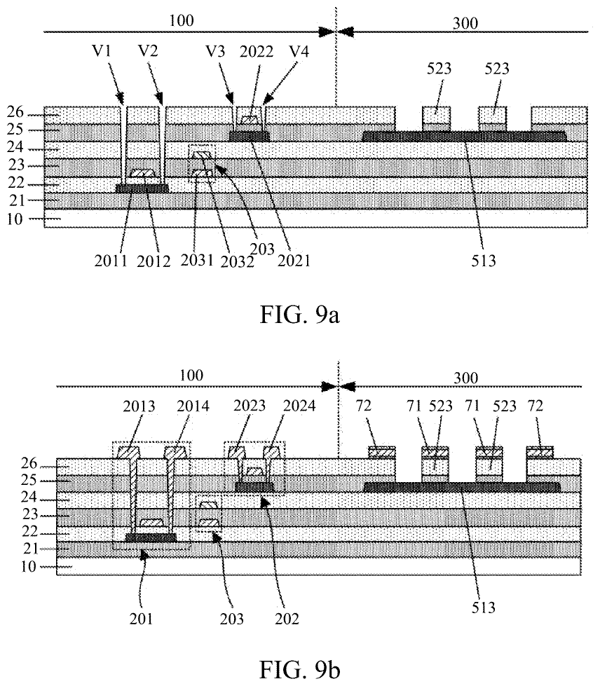

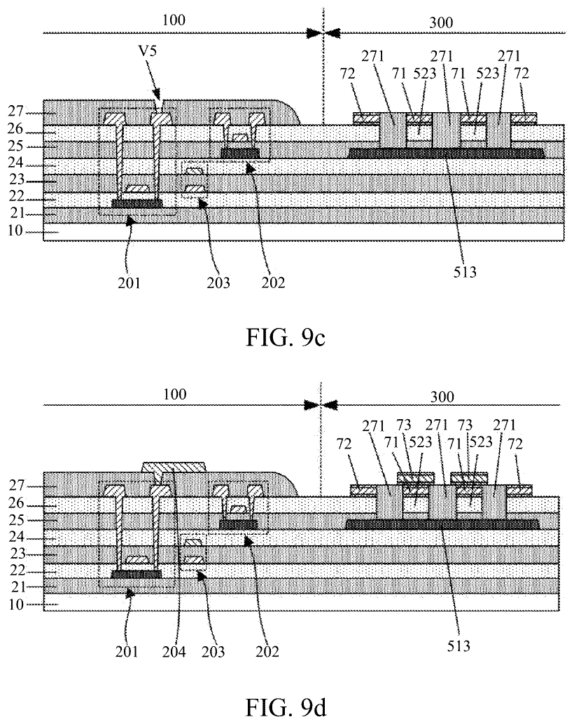

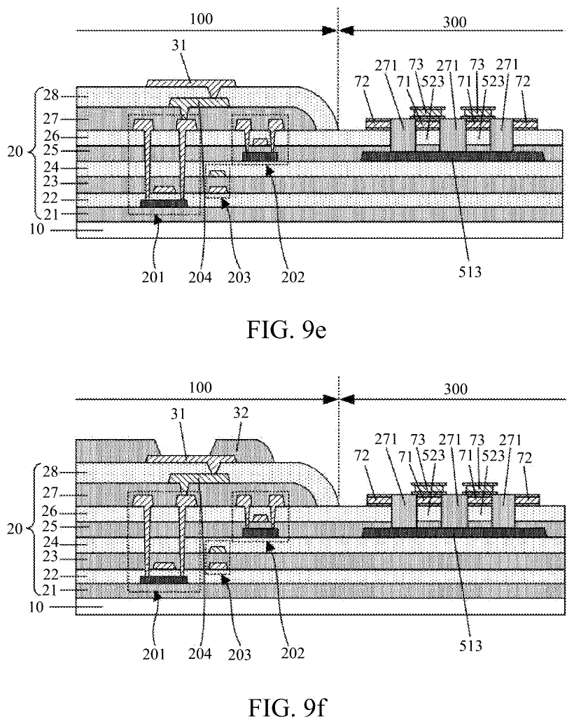

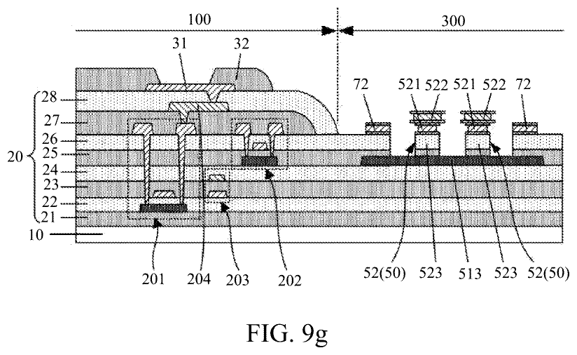

A first buffer thin film and a first semiconductor thin film are sequentially deposited on a base 10, and the first semiconductor thin film is patterned by a patterning process to form a first buffer layer 21 covering the base 10, and a pattern of a first semiconductor layer disposed on the first buffer layer 21. The pattern of the first semiconductor layer includes multiple first active layers 2011 located in a display region 100. After this patterning process, a transition region 300 includes the first buffer layer 21 disposed on the base 10, as shown in FIG. 9a.

Then, a first gate insulation thin film and a first gate metal thin film are sequentially deposited, and the first gate metal thin film is patterned by a patterning process to form a first gate insulation layer 22 covering the pattern of the first semiconductor layer and a pattern of a first gate metal layer disposed on the first gate insulation layer 22. The pattern of the first gate metal layer includes multiple first gate electrodes 2012 and multiple first electrode plates 2031 located in the display region 100. After this patterning process, the transition region 300 includes the first buffer layer 21 and the first gate insulation layer 22 sequentially stacked on the base 10, as shown in FIG. 9a.

Subsequently, a second gate insulation thin film and a second gate metal thin film are sequentially deposited, and the second gate metal thin film is patterned by a patterning process to form a second gate insulation layer 23 covering the first gate metal layer, and a pattern of a second gate metal layer disposed on the second gate insulation layer 23. The pattern of the second gate metal layer includes multiple second electrode plates 2032 located in the display region 100. The multiple second electrode plates 2032 and the multiple first electrode plates 2031 are disposed opposite to each other and form multiple storage capacitors 203. After this patterning process, the transition region 300 includes the first buffer layer 21, the first gate insulation layer 22 and the second gate insulation layer 23 sequentially stacked on the base 10, as shown in FIG. 9a.

Subsequently, a first interlayer insulation thin film and a second semiconductor thin film are deposited, and the second semiconductor thin film is patterned by a patterning process to form a first interlayer insulation layer 24 covering the pattern of the second gate metal layer, and a pattern of a second semiconductor layer provided on the first interlayer insulation layer 24. The pattern of the second semiconductor layer includes multiple second active layers 2021 located in the display region 100 and a blocking layer 513 located in the transition region 300. After this patterning process, the transition region 300 includes the first buffer layer 21, the first gate insulation layer 22, the second gate insulation layer 23, the first interlayer insulation layer 24, and the blocking layer 513 disposed on the first interlayer insulation layer 24, which are sequentially stacked on the base 10, as shown in FIG. 9a.

Subsequently, a third gate insulation thin film and a third gate metal thin film are sequentially deposited, and the third gate metal thin film is patterned by a patterning process to form a third gate insulation layer 25 covering the pattern of the second semiconductor layer, and a pattern of a third gate metal layer disposed on the third gate insulation layer 25. The pattern of the third gate metal layer includes multiple second gate electrodes 2022 located in the display region 100. After this patterning process, the transition region 300 includes the first buffer layer 21, the first gate insulation layer 22, the second gate insulation layer 23, the first interlayer insulation layer 24, the blocking layer 513, and the third gate insulation layer 25 covering the blocking layer 513, which are sequentially stacked on the base 10, as shown in FIG. 9a.

Subsequently, a second interlayer insulation thin film is deposited, and the second interlayer insulation thin film is patterned by a patterning process to form a pattern of a second interlayer insulation layer 26 covering the pattern of the third gate metal layer. The second interlayer insulation layer 26 of the display region 100 is provided with multiple first via holes V1, multiple second via holes V2, multiple third via holes V3, and multiple fourth via holes V4. The multiple first via holes V1 expose one end of the multiple first active layers 2011, and the multiple second via holes V2 expose the other end of the multiple first active layers 2011. The multiple third via holes V3 expose one end of the multiple second active layers 2021, and the multiple fourth via holes V4 expose the other end of the multiple second active layers 2021. The second interlayer insulation layer 26 of the transition region 300 is provided with multiple grooves penetrating the third gate insulation layer 25 and exposing the blocking layer 513. The column base 523 of the isolation column 52 on the blocking layer 513 is formed between the adjacent grooves. The column base 523 includes the third gate insulation layer 25 and the second interlayer insulation layer 26 stacked, as shown in FIG. 9a.

Subsequently, a first source-drain metal thin film is deposited, and the first source-drain metal thin film is patterned by a patterning process to form a pattern of a first source-drain metal layer on the second interlayer insulation layer 26. The pattern of the first source-drain metal layer includes multiple first source electrodes 2013, multiple first drain electrodes 2014, multiple second source electrodes 2023, and multiple second drain electrodes 2024 located in the display region 100, and a first isolation layer 71 located on the column base 523 of the transition region 300 and a blocking wall 72 located on the second interlayer insulation layer 26. A side surface of the blocking wall 72 close to the groove may be flush with a side surface of the groove. The first source electrode 2013 is connected to one end of the first active layer 2011 through the first via hole V1, and the first drain electrode 2014 is connected to the other end of the first active layer 2011 through the second via hole V2. The second source electrode 2023 is connected to one end of the second active layer 2021 through the third via hole V3, and the second drain electrode 2024 is connected to the other end of the second active layer 2021 through the fourth via hole V4. The multiple first active layers 2011, the multiple first gate electrodes 2012, the multiple first source electrodes 2013, and the multiple first drain electrodes 2014 of the display region 100 form the multiple first transistors 201. The multiple second active layers 2021, the multiple second gate electrodes 2022, the multiple second source electrodes 2023, and the multiple second drain electrodes 2024 form the multiple second transistors 202. As shown in FIG. 9b, one first transistor 201 and one second transistor 202 are illustrated in FIG. 9b.

The first source-drain metal layer may include a first metal layer, a second metal layer, and a third metal layer sequentially stacked in a direction away from the base 10. For example, the first metal layer and the third metal layer may be a titanium layer, and the second metal layer 302 may be an aluminum layer. Then, the first source electrode 2013, the first drain electrode 2014, the second source electrode 2023, the second drain electrode 2024, the first isolation layer 71, and the blocking wall 72 all include the first metal layer, the second metal layer, and the third metal layer sequentially stacked in a direction away from the base 10.

Subsequently, a first planarization thin film is coated, and the first planarization thin film is patterned by a patterning process to form a pattern of a first planarization layer 27 covering the pattern of the first source-drain metal layer of the display region 100. The first planarization layer 27 is provided with a fifth via hole V5 in the display region 100, and the first planarization layer 27 in the fifth via hole V5 is removed and a surface of the first source electrode 2013 or the first drain electrode 2014 is exposed. The pattern of the first planarization layer 27 includes a filling layer 271 located in the transition region 300 and filled in the groove, and the filling layer 271 can fill and level up the groove. A surface of the filling layer 271 away from the base 10 can be flush with a surface of the first isolation layer 71 and the blocking wall 72 away from the base 10, as shown in FIG. 9c.

Subsequently, a second source-drain metal thin film is deposited, and the second source-drain metal thin film is patterned by a patterning process to form a pattern of a second source-drain metal layer on the first planarization layer 27. The pattern of the second source-drain metal layer includes multiple anode connection electrodes 204 located in the display region 100, and a second isolation layer 73 located on the first isolation layer 71 of the transition region 300. The anode connection electrode 204 is connected to the first source electrode 2013 or the first drain electrode 2014 through the fifth via hole V5. The second isolation layer 73 is also partially located on the filling layer 271. A side surface of the second isolation layer 73 facing the display region 100 or/and the hole region 200 protrudes from the corresponding side surface of the first isolation layer 71, as shown in FIG. 9d.

A film layer structure and a material of the second source-drain metal layer may be the same as a film layer structure and a material of the first source-drain metal layer. For example, the second source-drain metal layer may include a fourth metal layer, a fifth metal layer, and a sixth metal layer sequentially stacked in a direction away from the base 10. For example, the fourth metal layer and the sixth metal layer may be a titanium layer, and the fifth metal layer may be an aluminum layer. Then, the anode connection electrode 204 and the second isolation layer 73 each include the fourth metal layer, the fifth metal layer, and the sixth metal layer sequentially stacked in a direction away from the base 10.

Subsequently, a second planarization thin film is coated, and the second planarization thin film is patterned by a patterning process to form a pattern of a second planarization layer 28 covering the pattern of the second source-drain metal layer of the display region 100. The second planarization layer 28 is formed with multiple sixth via holes located in the display region 100. The second planarization layer 28 in the sixth via hole is removed and a surface of the anode connection electrode 204 is exposed, as shown in FIG. 9e.

Hereto, the preparation of the drive structure layer 20 and the film layers of the isolation column 52 is completed.

(2) Forming a light-emitting structure layer 30. In an exemplary embodiment, forming the light-emitting structure layer 30 may include the following operations.

A first electrode 31 thin film is deposited on the base 10 on which the aforementioned patterns are formed, and the first electrode 31 thin film is patterned by a patterning process to form a pattern of a first electrode layer. The pattern of the first electrode layer includes multiple first electrodes 31 (anodes) located in the display region 100. The first electrode 31 is connected to the anode connection electrodes 204 through the sixth via hole on the second planarization layer 28, so that the first electrode 31 is connected to the first source electrode 2013 or the first drain electrode 2014 through the anode connection electrode 204.

During a patterning process (such as a wet etching process) of the first electrode 31 thin film, the fifth metal layer of the second isolation layer 73 may be laterally etched simultaneously so that the fifth metal layer of the second isolation layer 73 is partially recessed inward relative to the fourth metal layer and the sixth metal layer on sides of the second isolation layer 73 facing the display region 100 and the hole region 200, as shown in FIG. 9e. In other embodiments, during the aforementioned patterning process (such as the development process) of the second planarization thin film, the fifth metal layer of the second isolation layer 73 may be laterally etched simultaneously, so that the fifth metal layer of the second isolation layer 73 is partially recessed inward relative to the fourth metal layer and the sixth metal layer on sides of the second isolation layer 73 facing the display region 100 and the hole region 200.

Subsequently, a pixel definition thin film is coated on the base 10 on which the aforementioned patterns are formed, and the pixel definition thin film is patterned by a patterning process to form a pattern of a pixel definition layer 32. The pixel definition layer 32 is provided with multiple pixel openings exposing a surface of the first electrode 31 of the display region 100, as shown in FIG. 9f.

Subsequently, the filling layer 271 in the groove is etched and removed by an etching process (dry etching or wet etching, for example, oxygen may be used as an etching gas). At the same time, portions of the fifth metal layer of the second isolation layer 73 and the second metal layer of the first isolation layer 71 are both laterally etched, so that on sides of the second isolation layer 73 and the first isolation layer 71 facing the display region 100 and the hole region 200, the fifth metal layer of the second isolation layer 73 is partially recessed inward relative to the fourth metal layer and the sixth metal layer, and the second metal layer of the first isolation layer 71 is partially recessed inward relative to the first metal layer and the third metal layer. This results in the first isolation layer 71 becoming the first isolation portion 521 of the isolation column 52 and the second isolation layer 73 becoming the second isolation portion 522 of the isolation column 52. The column base 523, the first isolation portion 521, and the second isolation portion 522 form the isolation column 52, as shown in FIG. 9g.

Subsequently, on the base 10 on which the aforementioned patterns are formed, multiple film layers of a light-emitting functional layer 33 may be sequentially formed by an evaporation process. The light-emitting functional layer 33 may include a hole injection layer, a hole transporting layer, an electron blocking layer, an organic light-emitting layer, a hole blocking layer, an electron transporting layer, and an electron injection layer, which are sequentially disposed in a direction away from the base. Except for the organic light-emitting layer, the remaining film layers of the light-emitting functional layer 33 may have an integrated monolithic structure. That is, the remaining film layers of the light-emitting functional layer 33 may be common layers for sub-pixels having different colors, and these common layers may be formed in the display region 100 and the transition region 300 at the time of evaporation. Due to the isolation column 52 provided in the transition region 300, these common layers are disconnected at the isolation columns 52, blocking the transmission path of water and oxygen from the hole region 200 to the display region 100 through the light-emitting functional layer 33, and preventing water and oxygen from eroding the light-emitting functional layer 33 of the display region 100, as shown in FIG. 6.

Subsequently, on the base 10 on which the aforementioned patterns are formed, a second electrode (cathode) layer is formed by an evaporation process. The second electrode layer 34 of sub-pixels having different colors is a common layer connected as an integrated structure, and the second electrode layer 34 may be formed in the display region 100 and the transition region 300. The second electrode layer 34 may be disconnected at the isolation column 52, blocking the transmission path of water and oxygen from the hole region 200 to the display region 100 through the second electrode layer 34, and preventing water and oxygen from eroding the second electrode layer 34 of the display region 100, as shown in FIG. 6.

Hereto, the preparation of the light-emitting structure layer 30 is completed.

(3) Forming an encapsulation structure layer 40. In an exemplary embodiment, forming the encapsulation structure layer 40 may include the following operations.

On the base 10 on which the aforementioned patterns are formed, a first encapsulation thin film is first deposited using an open mask by a deposition method to form a first encapsulation layer 41 located in the display region 100 and the transition region 300. Subsequently, a second encapsulation material is printed using an open mask by an ink jet printing process to form a second encapsulation layer 42 located in the display region 100 and the transition region 300. The isolation dam 60 of the transition region 300 may block ink overflow during the ink jet printing process. Subsequently, a third encapsulation thin film is deposited using an open mask by a deposition method to form a third encapsulation layer 43 located in the display region 100 and the transition region 300. The first encapsulation layer 41 and the third encapsulation layer 243 may be made of an inorganic material, and the second encapsulation layer 42 may be made of an organic material, as shown in FIG. 6.

Subsequently, film layers such as a touch structure layer and a color film layer may be sequentially formed on a side of the encapsulation structure layer 40 away from the base 10.

An embodiment of the present disclosure further provides a display device, which includes the display substrate according to any one of the previous embodiments. The display device may be any product or component with a display function, such as a mobile phone, a tablet computer, a television, a display, a laptop computer, a digital photo frame, and a navigator.

In the accompanying drawings, a size of a constituent element, and a thickness of a layer or a region are sometimes exaggerated for clarity. Therefore, an implementation of the present disclosure is not necessarily limited to the size, and the shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus includes a state in which the angle is above −5° and below 5°. In addition, “perpendicular” refers to a state in which an angle formed by two straight lines is above 80° and below 100°, and thus includes a state in which the angle is above 85° and below 95°.

In the description herein, orientation or position relationships indicated by the terms “upper”, “lower”, “left”, “right”, “top”, “inside”, “outside”, “axial”, “four corners” and the like are orientation or position relationships shown in the drawings, and are intended to facilitate description of the embodiments of the present disclosure and simplification of the description, but not to indicate or imply that the mentioned structure has a specific orientation or is constructed and operated in a specific orientation, therefore, they should not be understood as limitations on the present disclosure.

In the description herein, unless otherwise specified and defined explicitly, terms “connection”, “fixed connection”, “installation”, and “assembly” should be understood in a broad sense. For example, it may be a fixed connection, a detachable connection, or an integrated connection; terms “installation”, “connection”, and “fixed connection” may be a direct connection, an indirect connection through an intermediary, or communication inside two elements. For those ordinarily skilled in the art, meanings of the above terms in the embodiments of the present disclosure may be understood according to situations.

1. A display substrate comprising a hole region, a transition region surrounding the hole region, and a display region surrounding the transition region; the transition region being provided with an isolation structure surrounding the hole region, and the isolation structure comprising at least one isolation undercut;
the display substrate comprising a base, and the isolation undercut comprising a groove and a blocking edge disposed on a side of the groove away from the base; in a direction perpendicular to the base, the transition region comprising a first structure layer and a second structure layer sequentially stacked in a direction away from the base, the first structure layer comprising a blocking layer, the groove penetrating the second structure layer and exposing at least a portion of a surface of the blocking layer, the blocking edge being disposed on a surface of the second structure layer away from the base, and a portion of the blocking edge extending in a direction parallel to the base and protruding from a side wall of the groove.

2. The display substrate according to claim 1, wherein the blocking edge comprises a fourth metal layer, a fifth metal layer, and a sixth metal layer sequentially disposed in the direction away from the base, and the fifth metal layer is recessed inward relative to the fourth metal layer and the sixth metal layer on a side of the blocking edge close to the groove.

3. The display substrate according to claim 1, wherein the display region comprises a drive structure layer and a light-emitting structure layer sequentially stacked on the base, the drive structure layer comprises a pixel drive circuit, the pixel drive circuit comprises a plurality of transistors and a storage capacitor, the light-emitting structure layer comprises a plurality of light-emitting elements, and each light-emitting element comprises a first electrode, a light-emitting functional layer, and a second electrode layer sequentially stacked in the direction away from the base;
in the direction perpendicular to the base, the drive structure layer comprises a first source-drain metal layer, a first planarization layer, a second source-drain metal layer, and a second planarization layer sequentially disposed in the direction away from the base; the first source-drain metal layer comprises a first source electrode and a first drain electrode of a first transistor, and the second source-drain metal layer comprises a connection electrode connected to the first source electrode or the first drain electrode, and the connection electrode is also connected to the first electrode; and
the blocking edge is disposed in the same layer as the connection electrode, or the blocking edge is disposed in the same layer as the first source electrode and the first drain electrode.

4. The display substrate according to claim 3, wherein in the direction perpendicular to the base, the drive structure layer further comprises a first semiconductor layer, a first gate metal layer, and a second gate metal layer disposed on a side of the first source-drain metal layer close to the base; the first semiconductor layer comprises a first active layer of the first transistor, the first gate metal layer comprises a first gate electrode of the first transistor and one electrode plate of the storage capacitor, and the second gate metal layer comprises the other electrode plate of the storage capacitor; and
the blocking layer is disposed in the same layer as the first active layer, the first gate metal layer, or the second gate metal layer.

5. The display substrate according to claim 3, wherein in the direction perpendicular to the base, the drive structure layer further comprises a first semiconductor layer, a first gate metal layer, a second gate metal layer, a second semiconductor layer, and a third gate metal layer disposed on a side of the first source-drain metal layer close to the base; the first semiconductor layer comprises a first active layer of the first transistor, the first gate metal layer comprises a first gate electrode of the first transistor and one electrode plate of the storage capacitor, the second gate metal layer comprises the other electrode plate of the storage capacitor, the second semiconductor layer comprises a second active layer of a second transistor, and the third gate metal layer comprises a second gate electrode of the second transistor; the first source-drain metal layer further comprises a second source electrode and a second drain electrode of the second transistor; and
the blocking layer is disposed in the same layer as any film layer of the first active layer, the first gate metal layer, the second gate metal layer, the second active layer, and the third gate metal layer.

6. The display substrate according to claim 1, wherein the second structure layer comprises a plurality of inorganic insulation layers stacked, or the second structure layer comprises at least one inorganic insulation layer and at least one metal layer.

7. The display substrate according to claim 6, wherein the side wall of the groove is provided with one protruding ring or a plurality of protruding rings, the plurality of protruding rings are sequentially disposed in the direction perpendicular to the base, and the protruding ring is formed by an inorganic insulation layer.

8. The display substrate according to claim 3, wherein the isolation structure further comprises at least one isolation column; the isolation column comprises a first isolation portion and a second isolation portion sequentially disposed in the direction away from the base, and the second isolation portion is disposed protruding from the first isolation portion on a side of the isolation column facing the display region or/and the hole region; and
a material of the first isolation portion is an inorganic insulation material, and a material of the second isolation portion is a metal material; the second isolation portion is disposed in the same layer as the first source electrode and the first drain electrode; or, the second isolation portion is disposed in the same layer as the connection electrode; or, the second isolation portion comprises a first sub-isolation portion and a second sub-isolation portion sequentially stacked in the direction away from the base, the first sub-isolation portion is disposed in the same layer as the first source electrode and the first drain electrode, and the second sub-isolation portion is disposed in the same layer as the connection electrode.

9. The display substrate according to claim 8, wherein one isolation column is formed between two adjacent isolation undercuts, the blocking edge is disposed in the same layer as the second isolation portion and has the same material as the second isolation portion, and the second structure layer between two adjacent grooves is the first isolation portion.

10. The display substrate according to claim 9, wherein two adjacent blocking layers are not connected, and at least a portion of an orthographic projection of the second isolation portion on the base does not overlap with an orthographic projection of the two adjacent blocking layers on the base.

11. The display substrate according to claim 9, wherein at least two adjacent blocking layers are integrally connected, and an orthographic projection of the at least two adjacent blocking layers integrally connected on the base comprises an orthographic projection of the at least one isolation column on the base.

12. The display substrate according to claim 3, wherein the isolation structure further comprises at least one isolation column; the isolation column comprises a first isolation portion and a second isolation portion sequentially disposed in the direction away from the base, and the second isolation portion is disposed protruding from the first isolation portion on a side of the isolation column facing the display region or/and the hole region;
materials of the first isolation portion and the second isolation portion are both metal materials, the first isolation portion is disposed in the same layer as the first source electrode and the first drain electrode, and the second isolation portion is disposed in the same layer as the connection electrode; and
the isolation column further comprises a column base disposed on a side of the first isolation portion facing the base, and the column base comprises at least one inorganic insulation layer.

13. The display substrate according to claim 12, wherein the first isolation portion comprises a first metal layer, a second metal layer, and a third metal layer sequentially disposed in the direction away from the base, and the second metal layer is recessed inward relative to the first metal layer and the third metal layer on a side of the isolation column facing the display region or/and the hole region;
or/and, the second isolation portion comprises a fourth metal layer, a fifth metal layer, and a sixth metal layer sequentially disposed in the direction away from the base, and the fifth metal layer is recessed inward relative to the fourth metal layer and the sixth metal layer on a side of the isolation column facing the display region or/and the hole region.

14. The display substrate according to claim 8, wherein the first isolation portion comprises a silicon oxide film layer and a silicon nitride film layer sequentially stacked in the direction away from the base, and the silicon nitride film layer has a thickness of 0.5 μm to 1 μm.

15. A display device, comprising the display substrate according to claim 1.

16. A method for preparing the display substrate according to claim 1, comprising:
sequentially forming a first structure layer and a second structure layer on a base of a transition region, the first structure layer comprising a blocking layer, the second structure layer being provided with a groove, the groove penetrating the second structure layer and exposing at least a portion of a surface of the blocking layer;
forming a filling layer within the groove, the filling layer filling and leveling up the groove;
forming a blocking edge on a surface of the second structure layer away from the base, a portion of the blocking edge extending onto a surface of the filling layer away from the base in a direction parallel to the base; and
removing the filling layer.

17. A display device, comprising the display substrate according to claim 2.

18. A display device, comprising the display substrate according to claim 3.

19. A display device, comprising the display substrate according to claim 4.

20. A display device, comprising the display substrate according to claim 5.
